(19) United States
(12) Patent Application Publication
(10) Pub. No.: US 2026/0004743 A1
(43) Pub. Date: Jan. 1, 2026

(54) DISPLAY APPARATUS AND ELECTRONIC APPARATUS INCLUDING THE SAME

(71) Applicant: Samsung Display Co., Ltd., Yongin-si (KR)

(72) Inventors: Namhyun Kim, Yongin-si (KR); Youngkuk Kim, Yongin-si (KR)

(21) Appl. No.: 19/255,492

(22) Filed: Jun. 30, 2025

(30) Foreign Application Priority Data
Jul. 1, 2024 (KR) 10-2024-0086413

(51) Int. Cl. G09G 3/3266; G09G 3/32; G09G 3/3233; G09G 3/3275

(52) U.S. Cl. CPC G09G 3/3266; G09G 3/3233; G09G 3/32; G09G 3/3275; G09G 2300/0426; G09G 2300/0819; G09G 2300/0852; G09G 2300/0861; G09G 2310/0286

(57) ABSTRACT

A display apparatus includes: a substrate comprising a display region and a non-display region surrounding the display region; and a gate driving circuit in the non-display region of the substrate and comprising a plurality of stages, wherein each of the plurality of stages comprises a peripheral oxide transistor, comprising a first semiconductor layer comprising an oxide semiconductor, and a peripheral silicon transistor, comprising a second semiconductor layer comprising a silicon semiconductor, the peripheral oxide transistor further comprises a first lower gate electrode under the first semiconductor layer and a first upper gate electrode above the first semiconductor layer, and the first lower gate electrode and the first upper gate electrode are electrically connected to each other.

### CROSS-REFERENCE TO RELATED APPLICATION

The present application claims priority to and the benefit of Korean Patent Application No. 10-2024-0086413, filed on Jul. 1, 2024, in the Korean Intellectual Property Office, the entire disclosure of which is incorporated herein by reference.

### BACKGROUND

### 1. Field

Aspects of some embodiments of the present disclosure relate to a structure of a display apparatus.

### 2. Description of the Related Art

Generally, display apparatuses include light-emitting devices, such as light-emitting diodes, and thin-film transistors formed on a substrate, and operate as the light-emitting devices emit light.

A display apparatus includes a pixel region including a plurality of pixels, a gate driving circuit, a data driving circuit, a controller, etc. The gate driving circuit includes stages connected to gate lines, and the stages supply gate signals to the gate lines connected to the stages in response to signals from the controller.

The above information disclosed in this Background section is only for enhancement of understanding of the background and therefore the information discussed in this Background section does not necessarily constitute prior art.

### SUMMARY

Aspects of some embodiments include a driving circuit capable of relatively stably outputting a gate signal, and a display apparatus including the same. However, the embodiments are only examples, and the scope of embodiments according to the present disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate including a display region and a non-display region surrounding the display region, and a gate driving circuit arranged in the non-display region of the substrate and including a plurality of stages, wherein each of the plurality of stages includes a peripheral oxide transistor including a first semiconductor layer including an oxide semiconductor, and a peripheral silicon transistor including a second semiconductor layer including a silicon semiconductor, the peripheral oxide transistor further includes a first lower gate electrode arranged under the first semiconductor layer and a first upper gate electrode arranged above the first semiconductor layer, and the first lower gate electrode and the first upper gate electrode are electrically connected to each other.

According to some embodiments, each of the plurality of stages may further include a first connection electrode that connects the first lower gate electrode to the first upper gate electrode.

According to some embodiments, the first connection electrode may be arranged on the first upper gate electrode, and the first connection electrode may be connected to each of the first lower gate electrode and the first upper gate electrode via a contact hole.

According to some embodiments, the peripheral silicon transistor may further include a second lower gate electrode arranged under the second semiconductor layer, and a second upper gate electrode arranged above the second semiconductor layer.

According to some embodiments, the second lower gate electrode may be electrically connected to the second upper gate electrode.

According to some embodiments, each of the plurality of stages may further include a second connection electrode that connects the second lower gate electrode to the second upper gate electrode.

According to some embodiments, the first connection electrode and the second connection electrode may be arranged on a same layer.

According to some embodiments, the second semiconductor layer may include a channel region, a source region arranged on one side of the channel region, and a drain region arranged on the other side of the channel region, and the second lower gate electrode may be electrically connected to the source region of the second semiconductor layer.

According to some embodiments, the first semiconductor layer and the second semiconductor layer may be arranged on different layers.

According to some embodiments, the second upper gate electrode may be arranged under the first lower gate electrode.

According to some embodiments, the peripheral silicon transistor may further include a first peripheral transistor connected between a first terminal, to which a start signal is input, and a first node, and including a gate connected to a clock terminal to which a clock signal is input, a second peripheral transistor connected between a second terminal, to which a first voltage is supplied, and a second node, and including a gate connected to the first node, a third peripheral transistor connected between the first node and a third node and including a gate connected to a third terminal to which a second voltage lower than the first voltage is supplied, a fourth peripheral transistor connected between the second terminal and an output terminal and including a gate connected to the second node, and a fifth peripheral transistor connected between the output terminal and the third terminal and including a gate connected to the third node, and the peripheral oxide transistor may further include a sixth peripheral transistor connected between the second node and the third terminal and including a gate connected to the third node.

According to some embodiments, each of the plurality of stages may further include a first capacitor connected between the output terminal and the third node, and a second capacitor connected between the second terminal and the second node.

According to some embodiments, the display apparatus may further include a pixel circuit arranged in the display region of the substrate, and a light-emitting diode electrically connected to the pixel circuit, wherein the pixel circuit may include a main oxide transistor, including a third semiconductor layer including an oxide semiconductor, and a main silicon transistor, including a fourth semiconductor layer including a silicon semiconductor, the main oxide transistor may further include a third lower gate electrode arranged under the third semiconductor layer and a third upper gate electrode arranged above the third semiconductor layer, and the third semiconductor layer and the fourth semiconductor layer may be arranged on different layers.

According to some embodiments, the pixel circuit may further include a third connection electrode that electrically connects the third lower gate electrode to the third upper gate electrode.

According to some embodiments, the main silicon transistor may further include a first main transistor connected between a driving voltage line and the light-emitting diode and configured to control a current supplied to the light-emitting diode, a second main transistor connected between a data line and a first main node connected to a first terminal of the first main transistor, a third main transistor connected between the driving voltage line and the first main node, and a fourth main transistor connected between the first main transistor and the light-emitting diode, and the main oxide transistor may further include a fifth main transistor connected between a second main node connected to a gate of the first main transistor and a third main node connected to a second terminal of the first main transistor, and a sixth main transistor connected between a first initialization voltage line and the second main node.

According to some embodiments, each of the fifth main transistor and the sixth main transistor may include a structure in which the third lower gate electrode and the third upper gate electrode are electrically connected to each other.

According to some embodiments, the pixel circuit may further include a first main capacitor connected between the driving voltage line and the second node, and the main silicon transistor may further include a seventh main transistor connected between a second initialization voltage line and the light-emitting diode.

According to some embodiments, the main oxide transistor may further include a first main transistor connected between a driving voltage line and the light-emitting diode and configured to control a current supplied to the light-emitting diode, a second main transistor connected between a data line and a first main node connected to a gate of the first main transistor, a third main transistor connected between a reference voltage line and the first main node, and a fourth main transistor connected between an initialization voltage line and the light-emitting diode, and the main silicon transistor may further include a fifth main transistor connected between the driving voltage line and the first main transistor, and a sixth main transistor connected between a second main node connected to a first terminal of the first main transistor and the light-emitting diode.

According to some embodiments, at least one of the first main transistor, the second main transistor, the third main transistor, or the fourth main transistor may have a structure in which the third lower gate electrode and the third upper gate electrode are electrically connected to each other.

According to some embodiments, the pixel circuit may further include a first main capacitor connected between the first main node and the second main node, and a second main capacitor connected between the driving voltage line and the second main node.

According to one or more embodiments, a display apparatus includes a

substrate including a display region and a non-display region surrounding the display region, and a gate driving circuit arranged in the non-display region of the substrate and including a plurality of stages, wherein each of the plurality of stages includes a first peripheral transistor connected between a first terminal, to which a start signal is input, and a first node, and including a gate connected to a clock terminal to which a clock signal is input, a second peripheral transistor connected between a second terminal, to which a first voltage is supplied, and a second node, and including a gate connected to the first node, a third peripheral transistor connected between the first node and a third node and including a gate connected to a third terminal to which a second voltage lower than the first voltage is supplied, a fourth peripheral transistor connected between the second node and the third terminal and including a gate connected to the third node, a fifth peripheral transistor connected between the second terminal and an output terminal and including a gate connected to the second node, and a sixth peripheral transistor connected between the output terminal and the third terminal and including a gate connected to the third node, the fourth peripheral transistor further includes a first lower gate electrode, a first semiconductor layer arranged on the first lower gate electrode, and a first upper gate electrode arranged on the first semiconductor layer, and the first lower gate electrode and the first upper gate electrode are electrically connected to each other.

According to some embodiments, each of the plurality of stages may further include a first connection electrode that connects the first lower gate electrode to the first upper gate electrode.

According to some embodiments, each of the first peripheral transistor, the second peripheral transistor, the third peripheral transistor, the fifth peripheral transistor, and the sixth peripheral transistor may further include a second lower gate electrode, a second semiconductor layer arranged on the second lower gate electrode, and a second upper gate electrode arranged on the second semiconductor layer, and the second lower gate electrode and the second upper gate electrode may be electrically connected to each other.

According to some embodiments, the first semiconductor layer and the second semiconductor layer may be arranged on different layers.

According to some embodiments, the first semiconductor layer may include an oxide semiconductor, and the second semiconductor layer may include a silicon semiconductor.

According to some embodiments, the display apparatus may further include a pixel circuit arranged in the display region of the substrate, and a light-emitting diode electrically connected to the pixel circuit, wherein the pixel circuit may include a first main transistor connected between a driving voltage line and the light-emitting diode and configured to control a current supplied to the light-emitting diode, a second main transistor connected between a data line and a first main node connected to a first terminal of the first main transistor, a third main transistor connected between a second main node connected to a gate of the first main transistor and a third main node connected to a second terminal of the first main transistor, a fourth main transistor connected between a first initialization voltage line and the second main node, a fifth main transistor connected between the driving voltage line and the first main node, a sixth main transistor connected between the third node and the light-emitting diode, and a seventh main transistor connected between a second initialization voltage line and the light-emitting diode.

According to some embodiments, each of the third main transistor and the fourth main transistor may include a third lower gate electrode, a third semiconductor layer arranged on the third lower gate electrode, and a third upper gate electrode arranged on the third semiconductor layer, and the third lower gate electrode and the third upper gate electrode may be electrically connected to each other.

According to some embodiments, the third semiconductor layer may include an oxide semiconductor.

According to some embodiments, the display apparatus may further include a pixel circuit arranged in the display region of the substrate, and a light-emitting diode electrically connected to the pixel circuit, wherein the pixel circuit may include a first main transistor connected between a driving voltage line and the light-emitting diode and configured to control a current supplied to the light-emitting diode, a second main transistor connected between a data line and a first main node connected to a gate of the first main transistor, a third main transistor connected between a reference voltage line and the first main node, a fourth main transistor connected between an initialization voltage line and the light-emitting diode, a fifth main transistor connected between the driving voltage line and the first main transistor, and a sixth main transistor connected between a second main node connected to a first terminal of the first main transistor and the light-emitting diode.

According to some embodiments, at least one of the first main transistor, the second main transistor, the third main transistor, or the fourth main transistor may include a fourth lower gate electrode, a fourth semiconductor layer arranged on the fourth lower gate electrode, and a fourth upper gate electrode arranged on the fourth semiconductor layer, and the fourth lower gate electrode and the fourth upper gate electrode may be electrically connected to each other.

According to some embodiments, the fourth semiconductor layer may include an oxide semiconductor.

According to one or more embodiments, an electronic apparatus comprising a display apparatus, wherein the display apparatus comprises: a substrate comprising a display region and a non-display region surrounding the display region; and a gate driving circuit in the non-display region of the substrate and comprising a plurality of stages, wherein each of the plurality of stages comprises a peripheral oxide transistor, comprising a first semiconductor layer comprising an oxide semiconductor, and a peripheral silicon transistor, comprising a second semiconductor layer comprising a silicon semiconductor, the peripheral oxide transistor further comprises a first lower gate electrode under the first semiconductor layer and a first upper gate electrode above the first semiconductor layer, and the first lower gate electrode and the first upper gate electrode are electrically connected to each other.

According to some embodiments, the electronic apparatus may further include a display module, a processor, a power module, and a memory, wherein the display apparatus may include one of the display module, the processor, the power module, or the memory.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a plan view schematically showing a display apparatus according to some embodiments;

FIG. 2 is a block diagram schematically showing the display apparatus according to some embodiments;

FIG. 3 is a diagram schematically showing a driving circuit included in the display apparatus according to some embodiments;

FIGS. 4A and 4B are each a circuit diagram schematically showing an example of a stage included in a driving circuit of FIG. 1;

FIG. 5 is a cross-sectional view schematically showing a portion of a non-display region of the display apparatus according to some embodiments;

FIGS. 6A to 7B are graphs showing characteristics of an oxide transistor shown in FIG. 4A;

FIG. 8 is an equivalent circuit diagram schematically showing a light-emitting diode of the display apparatus according to some embodiments and a pixel circuit electrically connected to the light-emitting diode;

FIG. 9 is a cross-sectional view schematically showing a portion of a display region of the display apparatus according to some embodiments;

FIG. 10 is an equivalent circuit diagram schematically showing a light-emitting diode of the display apparatus according to some embodiments and a pixel circuit electrically connected to the light-emitting diode;

FIG. 11 is a cross-sectional view schematically showing a portion of a display region of the display apparatus according to some embodiments; and

FIG. 12 is a cross-sectional view schematically showing a portion of a non-display region of the display apparatus according to some embodiments.

FIG. 13 is a block diagram of an electronic apparatus according to an embodiment.

FIG. 14 is schematic diagrams of electronic apparatuses according to various embodiments.

### DETAILED DESCRIPTION

Reference will now be made in detail to embodiments, examples of which are illustrated in the accompanying drawings, wherein like reference numerals refer to like elements throughout the present specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not by being limited to the embodiments presented below.

Hereinafter, embodiments of the present disclosure will be described in detail with reference to the accompanying drawings, and in the description with reference to the drawings, the same or corresponding elements are indicated by the same reference numerals and redundant descriptions thereof are omitted.

In the following embodiments, it will be understood that although the terms “first,” “second,” etc. may be used herein to describe various elements, these elements should not be limited by these terms. These terms are only used to distinguish one element from another.

In the following embodiments, the expression of singularity in the present specification includes the expression of plurality unless clearly specified otherwise in context.

In the following embodiments, it will be further understood that the terms “comprises” and/or “comprising” used herein specify the presence of stated features or elements, but do not preclude the presence or addition of one or more other features or elements.

In the following embodiments, it will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, because sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or element is referred to as being “connected to” another layer, area, or element, it can be directly or indirectly connected to the other layer, region, or element. That is, for example, intervening layers, regions, or elements may be present. For example, in the present specification, when a layer, region, or element is electrically connected to another layer, region, or element, the layers, regions, or elements may not only be directly electrically connected, but may also be indirectly electrically connected via another layer, region, or element therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

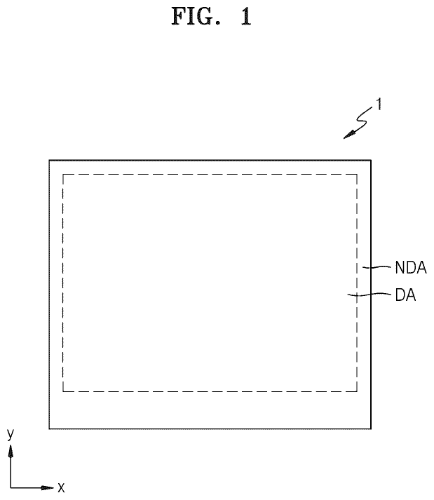

FIG. 1 is a plan view schematically showing a display apparatus according to some embodiments.

Referring to FIG. 1, a display apparatus 1 may include a display region DA and a non-display region NDA outside (e.g., in a periphery or outside a footprint of) the display region DA. The display region DA may be entirely surrounded by the non-display region NDA.

When viewed in a plan view, the display region DA may have a rectangular

shape. According to some embodiments, the display region DA may have a polygonal shape such as a triangle, pentagon, or hexagon, or may have a circular, oval, or irregular shape. The display region DA may have rounded corners.

The display apparatus 1 of FIG. 1 displays moving images (e.g., video images) or still images (e.g., static images), and may be used in a portable electronic device such as a mobile phone, a laptop, a tablet personal computer (PC), a smart phone, a mobile communication terminal, an electronic organizer, an e-book, a portable multimedia player (PMP), a navigation device, or an ultra mobile PC (UMPC). Alternatively, the display apparatus 1 may be used in a television, a monitor, a billboard, or an electronic device for the Internet of Things (IOT), or may be used in a wearable electronic device such as a smart watch, a watch phone, a display, a tablet, and a head-mounted display (HMD). In addition, the display apparatus 1 according to some embodiments may be used in an instrument panel of vehicles, a center information display (CID) arranged on the center fascia or dashboard of vehicles, a room mirror display in place of side-view mirrors of vehicles, or an electronic device for a display arranged at the rear side of a front seat as an entertainment for a rear seat of vehicles.

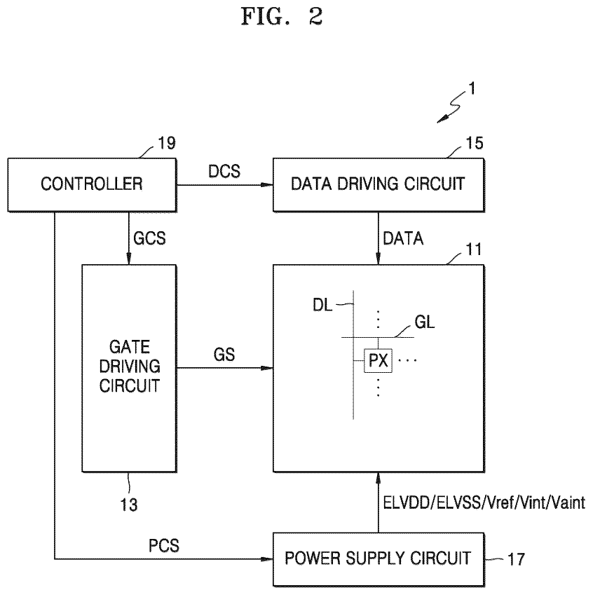

FIG. 2 is a block diagram schematically showing the display apparatus 1 according to some embodiments.

Referring to FIGS. 1 and 2, the display apparatus 1 according to some embodiments may include a pixel unit 11, a gate driving circuit 13, a data driving circuit 15, a power supply circuit 17, and a controller 19.

The pixel unit 11 may include a plurality of pixels PX provided in the display region DA (FIG. 1). The plurality of pixels PX may be arranged in various shapes, such as a stripe arrangement, a pentile arrangement (a diamond arrangement), and a mosaic arrangement, to implement an image. Each of the plurality of pixels PX may include a display element (for example, a light-emitting diode), and the display element may be electrically connected to a pixel circuit. The plurality of pixels PX may represent an image by using light emitted from the display element corresponding to each of the plurality of pixels PX. Each of the pixel circuits may be electrically connected to a gate line GL and a data line DL and may include a plurality of transistors and at least one capacitor.

Various conductive lines configured to transmit an electrical signal to be applied to the display region DA (FIG. 1), external circuits electrically connected to pixel circuits, and pads to which a printed circuit board or a driver IC chip is attached may be located in the non-display region NDA (FIG. 1). For example, the gate driving circuit 13, the data driving circuit 15, the power supply circuit 17, and the controller 19 may be provided in the non-display region NDA (FIG. 1).

The gate driving circuit 13 may be electrically connected to a plurality of gate lines GL and may be configured to generate a gate signal GS in response to a control signal GCS from the controller 19 and sequentially supply the gate signal GS to the gate lines GL. The gate signal GS may be a gate control signal that controls turning on and turning off of a transistor electrically connected to the gate line GL. The gate signal GS may be a square wave signal including an on voltage at which a transistor may be turned on and an off voltage at which a transistor may be turned off. According to some embodiments, the on voltage may be a high-level voltage (first level voltage) or a low-level voltage (second level voltage).

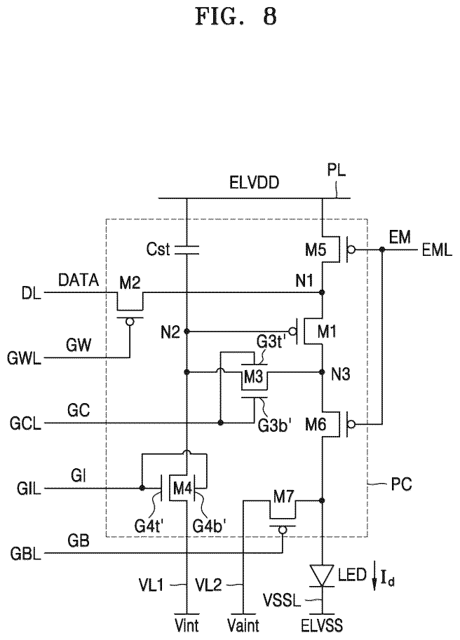

FIG. 2 shows that a pixel circuit corresponding to any pixel PX is connected to one gate line GL, but this is an example, and a pixel circuit corresponding to one pixel PX may be connected to at least two gate lines, and the gate driving circuit 13 may be configured to supply, respectively to the at least two gate lines, at least two gate signals GS that have different timings at which the on voltage is applied. For example, as shown in FIG. 8, the gate driving circuit 13 may be configured to apply a first gate signal GW (FIG. 8), a second gate signal GC (FIG. 8), a third gate signal EM

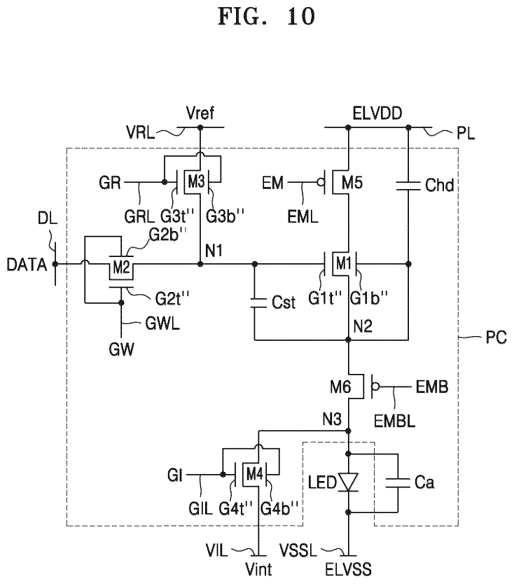

(FIG. 8), a fourth gate signal GI (FIG. 8), and a fifth gate signal GB (FIG. 8) to first to fifth gate lines, respectively, and the first to fifth gate lines may be connected to the pixel circuit. Alternatively, as shown in FIG. 10, the gate driving circuit 13 may be configured to apply a first gate signal GW (FIG. 10), a second gate signal GR (FIG. 10), a third gate signal EM (FIG. 10), a fourth gate signal GI (FIG. 10), and a fifth gate signal EMB to first to fifth gate lines, respectively, and the first to fifth gate lines may be connected to the pixel circuit.

The data driving circuit 15 may be connected to a plurality of data lines DL and may be configured to supply, to the data lines DL, a data signal DATA in response to a control signal DCS from the controller 19. The data signal DATA supplied to the data lines DL may be supplied to the pixel circuit. The data driving circuit 15 may be configured to convert input image data having a gray scale, which is input from the controller 19, into the data signal DATA in the form of voltage or current.

The power supply circuit 17 may be configured to generate voltages required to drive the pixel PX in response to a control signal PCS from the controller 19. The power supply circuit 17 may be configured to generate a driving voltage ELVDD and a common voltage ELVSS and supply the driving voltage ELVDD and the common voltage ELVSS to the pixels PX. The driving voltage ELVDD may be a high-level voltage provided to a first electrode (a pixel electrode or an anode) of the display element included in the pixel PX. The common voltage ELVSS may be a low-level voltage provided to a second electrode (an opposite electrode or a cathode) of the display element included in the pixel PX. The power supply circuit 17 may be configured to generate a reference voltage Vref, a first initialization voltage Vint, and a second initialization voltage Vaint and supply the reference voltage Vref, the first initialization voltage Vint, and the second initialization voltage Vaint to the pixels PX.

The voltage level of the driving voltage ELVDD may be higher than the voltage level of the common voltage ELVSS. The voltage level of the reference voltage

Vref may be lower than the voltage level of the driving voltage ELVDD. The voltage level of the first initialization voltage Vint may be higher than the voltage level of the second initialization voltage Vaint. The voltage level of the second initialization voltage Vaint may be lower than the voltage level of the common voltage ELVSS. The voltage level of the first initialization voltage Vint may be equal to the voltage level of the common voltage ELVSS or may be higher than the voltage level of the common voltage ELVSS.

The controller 19 may generate the control signals GCS, DCS, and PCS based on signals input from the outside, and may supply the control signals GCS, DCS, and PCS to the gate driving circuit 13, the data driving circuit 15, and the power supply circuit 17. The control signal GCS output to the gate driving circuit 13 may include a plurality of clock signals and a gate start signal. The control signal DCS output to the data driving circuit 15 may include a source start signal and clock signals.

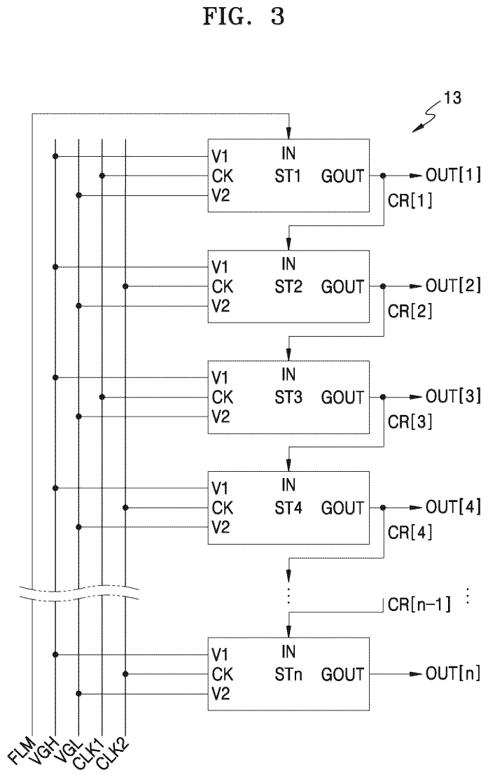

FIG. 3 is a diagram schematically showing a driving circuit included in the display apparatus 1 according to some embodiments.

Referring to FIG. 3, the gate driving circuit 13 according to some embodiments may include first to n^{th} stages ST1 to STn. The first to n^{th} stages ST1 to STn may sequentially output first to nth output signals OUT[1], OUT[2], OUT[3], OUT[4], . . . , and OUT[n] to signal lines.

Each of the first to n^{th} stages ST1 to STn may be connected to a signal line. Each of the first to n^{th} stages ST1 to STn may receive at least one clock signal and at least one voltage signal, and may generate an output signal OUT and output the output signal OUT to a connected signal line. The first to (n−1)^{th} stages ST1 to STn-1 may respectively generate carry signals CR[1], CR[2], CR[3], CR[4], . . . , and CR[n−1] and output the carry signals CR[1], CR[2], CR[3], CR[4], . . . , and CR[n−1] to respective subsequent stages. According to some embodiments, the carry signals CR[1], CR[2], CR[3], CR[4], . . . , and CR[n−1] may be output signals (hereinafter, referred to as “previous output signals”) output from respective previous stages.

Each of the first to n^{th} stages ST1 to STn may include a plurality of terminals to which a plurality of signals are input. The plurality of signals may include a clock signal and a voltage signal. The plurality of terminals may include an input terminal IN, a first voltage input terminal V1, a second voltage input terminal V2, a clock terminal CK, and an output terminal GOUT.

A start signal may be input (supplied) to the input terminal IN. The first to nth stages ST1 to STn may respectively output the first to n^{th} output signals OUT[1], OUT[2], OUT[3], OUT[4], . . . , and OUT[n] in response to the start signal. The start signal may be an external signal FLM or the carry signals CR[1], CR[2], CR[3], CR[4], . . . , and CR[n−1]. The external signal FLM is input as a start signal to the input terminal IN of the first stage ST1, and the previous output signals may be input as start signals to the respective input terminal IN of the second to n^{th} stages ST2 to STn. A previous stage may be located at least one stage prior to a current stage. In FIG. 3, a previous stage is a located immediately prior to a current stage. For example, the third output signal OUT[3] output from the third stage ST3 may be input, as a carry signal and a start signal, to the input terminal IN of the fourth stage ST4.

A first voltage VGH may be input to the first voltage input terminal V1, and a second voltage VGL may be input to the second voltage input terminal V2. The second voltage VGL may be lower than the first voltage VGH.

A clock signal CLK may be input to the clock terminal CK. The clock signal CLK may include a first clock signal CLK1 and a second clock signal CLK2. The first clock signal CLK1 or the second clock signal CLK2 may be input to the clock terminal CK. The first clock signal CLK1 may be input to the clock terminal CK of each of the odd-numbered stages (ST1, ST3, . . . ). The second clock signal CLK2 may be input to the clock terminal CK of each of the even-numbered stages (ST2, ST4, . . . ).

The first clock signal CLK1 and the second clock signal CLK2 may be square wave signals that repeat a high-level voltage and a low-level voltage. According to some embodiments, the first clock signal CLK1 and the second clock signal CLK2 may be square wave signals that repeat the first voltage VGH and the second voltage VGL. The first clock signal CLK1 and the second clock signal CLK2 may have the same waveform and may be phase-shifted signals. For example, the second clock signal CLK2 may have the same waveform as the first clock signal CLK1 and may be input with its phase shifted (phase delayed) at certain intervals. The second clock signal CLK2 may be shifted by a ½ cycle from the first clock signal CLK1. According to some embodiments, for one cycle of the first clock signal CLK1 and the second clock signal CLK2, a period in which a high-level voltage is maintained and a period in which a low-level voltage is maintained may be the same. According to some embodiments, for one cycle of the first clock signal CLK1 and the second clock signal CLK2, a period in which a high-level voltage is maintained may be longer than a period in which a low-level voltage is maintained.

An output signal may be output from the output terminal GOUT. The first to n^{th} output signals OUT[1], OUT[2], OUT[3], OUT[4], . . . , and OUT[n] output from the output terminals GOUT of the first to n^{th} stages ST1 to STn may be sequentially shifted by a certain period. According to some embodiments, the first to n^{th} stages ST1 to STn may shift the first to n^{th} output signals OUT[1], OUT[2], OUT[3], OUT[4], . . . , and OUT[n] having a high-level voltage by a ½ cycle of a clock signal and sequentially output the first to n^{th} output signals OUT[1], OUT[2], OUT[3], OUT[4], . . . , and OUT[n]. According to some embodiments, a high-level voltage and low-level voltage of output signals may respectively be the first voltage VGH and the second voltage VGL.

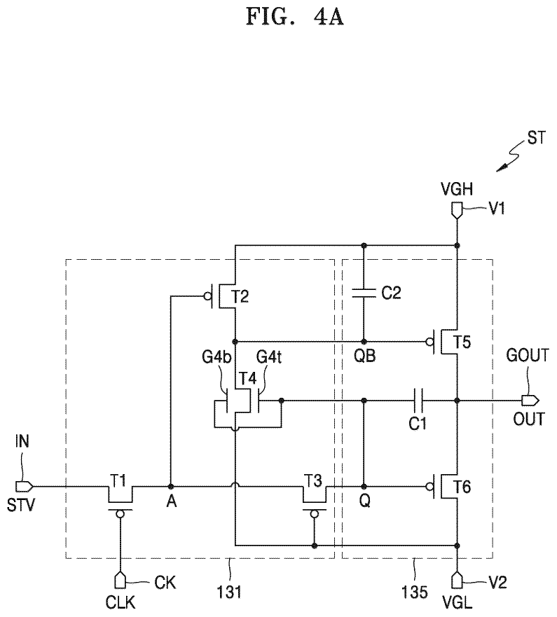

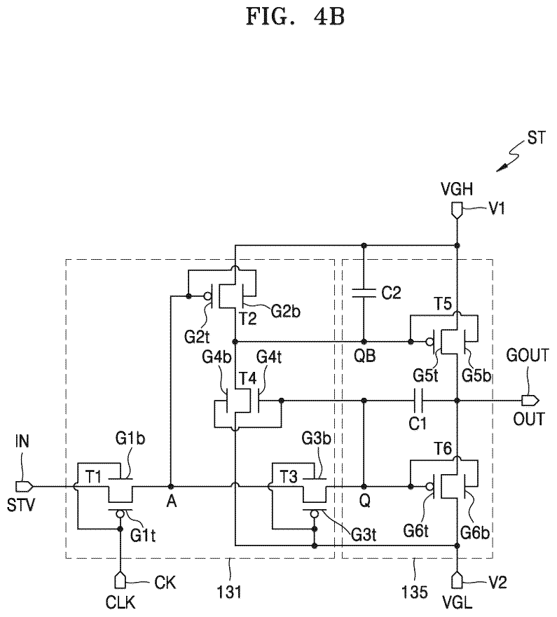

FIGS. 4A and 4B are each a circuit diagram schematically showing an example of a stage included in a driving circuit of FIG. 1. Although FIGS. 4A and 4B illustrate various components in a stage according to some embodiments, embodiments according to the present disclosure are not limited thereto, and according to various embodiments, the stage may include additional components or fewer components without departing from the spirit and scope of embodiments according to the present disclosure.

First, referring to FIG. 4A, a stage ST may include a control circuit 131 and an output circuit 135. Each of the control circuit 131 and the output circuit 135 may include at least one transistor. The at least one transistor may include an N-channel transistor and/or a P-channel transistor. According to some embodiments, the impurity conductivity type of a fourth transistor T4 of the stage ST may be opposite to the impurity conductivity type of the remaining transistors. For example, the fourth transistor T4 may be an N-channel transistor, and a first transistor T1, a second transistor T2, a third transistor T3, a fifth transistor T5, and a sixth transistor T6 may each be a P-channel transistor. At this time, the first to sixth transistors T1, T2, T3, T4, T5, and T6 are included in the gate driving circuit 13 (FIG. 2) arranged in the non-display region NDA (FIG. 1), and thus, the first to sixth transistors T1, T2, T3, T4, T5, and T6 may also be referred to as first to sixth peripheral transistors, respectively.

The P-channel transistor may be a silicon transistor. The silicon transistor may include a silicon semiconductor, and the silicon semiconductor may include amorphous silicon, polysilicon, etc. For example, the silicon transistor may be a low-temperature polycrystalline silicon (LTPS) thin-film transistor.

The N-channel transistor may be an oxide transistor. The oxide transistor may include an oxide semiconductor, and the oxide semiconductor may include Zn oxide, In—Zn oxide, Ga—In—Zn oxide, etc., as a Zn oxide-based material. In some embodiments, the oxide semiconductor may be an In—Ga—Zn—O (IGZO) semiconductor. In some embodiments, the oxide semiconductor may be an In—Sn—Ga—Zn—O (ITGZO) semiconductor. For example, the oxide transistor may be a low-temperature polycrystalline oxide (LTPO) thin-film transistor.

A gate-on voltage of the P-channel transistor may be a low-level voltage, and a gate-off voltage may be a high-level voltage. A gate-on voltage of the N-channel transistor may be a high-level voltage, and a gate-off voltage may be a low-level voltage.

The control circuit 131 may be configured to control voltages at a first node A, a second node QB, and a third node Q in response to a signal input to the input terminal IN. For example, the control circuit 131 may be configured to control voltages at the first node A, the second node QB, and the third node Q in response to a start signal STV (for example, the external signal FLM or a carry signal CR (FIG. 3)). According to some embodiments, the carry signal CR may be a previous output signal. The control circuit 131 may include the first to fourth transistors T1 to T4.

The first transistor T1 may be connected between the input terminal IN and the first node A. A gate of the first transistor T1 may be connected to the clock terminal CK. The first transistor T1 may be turned on when the clock signal CLK input to the clock terminal CK is at a low level, to transmit, to the first node A, the start signal STV input to the input terminal IN. The clock signal CLK may be the first clock signal CLK1 (FIG. 3) or the second clock signal CLK2 (FIG. 3). According to some embodiments, the first clock signal CLK1 (FIG. 3) may be input to the clock terminal CK of an odd-numbered stage, and the second clock signal CLK2 (FIG. 3) may be input to the clock terminal CK of an even-numbered stage. According to some embodiments, the second clock signal CLK2 (FIG. 3) may be input to the clock terminal CK of an odd-numbered stage, and the first clock signal CLK1 (FIG. 3) may be input to the clock terminal CK of an even-numbered stage.

The second transistor T2 may be connected between the first voltage input terminal V1 and the second node QB. A gate of the second transistor T2 may be connected to the first node A. The second transistor T2 may be turned on when the start signal STV transmitted to the first node A is at a low level, to transmit, to the second node QB, the first voltage VGH input to the first voltage input terminal V1. Due to the second transistor T2, the voltage level of the voltage at the second node QB may be opposite to the voltage level of the voltage at the first node A.

The third transistor T3 may be connected between the first node A and the third node Q. A gate of the third transistor T3 may be connected to the second voltage input terminal V2. The third transistor T3 may be turned on by the second voltage VGL input to the second voltage input terminal V2, and may be configured to transmit, to the third node Q, the start signal STV transmitted via the first transistor T1. The third transistor T3 may always be turned on. Stress of the first transistor T1 due to voltage fluctuations at the third node Q may be alleviated by the third transistor T3.

The fourth transistor T4 may be connected between the second node QB and the second voltage input terminal V2. A gate of the fourth transistor T4 may include a fourth upper gate electrode G4t and a fourth lower gate electrode G4b. The fourth upper gate electrode G4t of the fourth transistor T4 may be connected to the third node Q. The fourth transistor T4 may be turned on when the start signal STV transmitted to the third node Q is at a high level, to transmit, to the second node QB, the second voltage VGL input to the second voltage input terminal V2. Due to the fourth transistor T4, the voltage level of the voltage at the second node QB may be opposite to the voltage level of the voltage at the third node Q.

Each of the second transistor T2 and the fourth transistor T4 may be configured to control the voltage level of the voltage at the second node QB according to the voltage level of the voltage at the first node A or the third node Q, and thus, may function as an inverter or a level shifter.

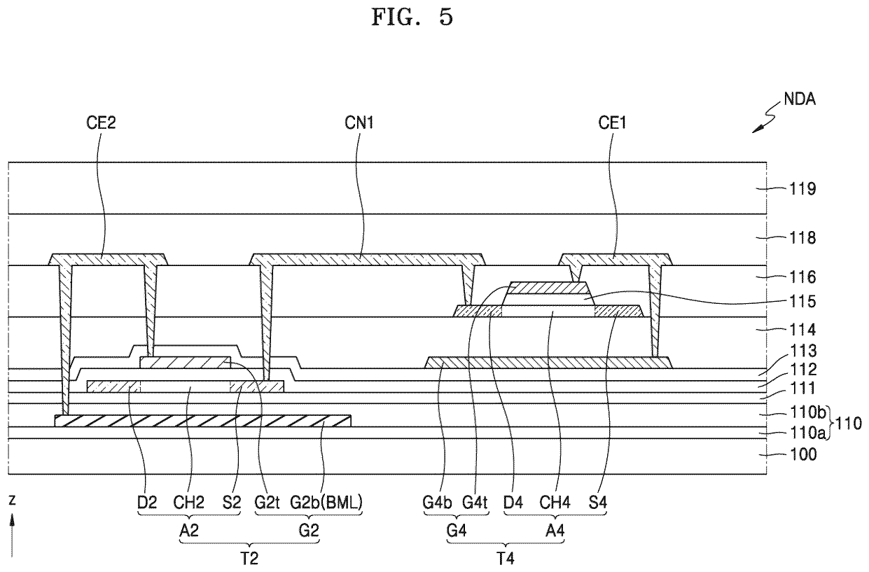

According to some embodiments, the fourth lower gate electrode G4b of the fourth transistor T4 may be electrically connected to the fourth upper gate electrode G4t. In other words, an oxide transistor included in the stage ST may have a double-gate structure in which a gate-on voltage is applied to the fourth upper gate electrode G4t and the fourth lower gate electrode G4b. When the gate-on voltage is applied to the fourth upper gate electrode G4t and the fourth lower gate electrode G4b, a voltage difference between the fourth upper gate electrode G4t and the fourth lower gate electrode G4b is eliminated and electron mobility may be relatively improved, and thus, driving characteristics and reliability of the fourth transistor T4 may be relatively improved. The double-gate structure in which the fourth lower gate electrode G4b and the fourth upper gate electrode G4t are connected are described in detail with reference to FIG. 5.

The output circuit 135 may be connected between the first voltage input terminal V1 and the second voltage input terminal V2. The output circuit 135 may be configured to output the output signal OUT having a high-level voltage or a low-level voltage according to the voltage levels of the second node QB and the third node Q. The output circuit 135 may include the fifth transistor T5 and the sixth transistor T6. The output circuit 135 may further include a first capacitor C1 and a second capacitor C2.

The fifth transistor T5 may be connected between the first voltage input terminal V1 and the output terminal GOUT. A gate of the fifth transistor T5 may be connected to the second node QB. The fifth transistor T5 may be a pull-up transistor configured to transmit a high-level voltage to the output terminal GOUT. The fifth transistor T5 may be turned on when the voltage at the second node QB is at a low level, to output the first voltage VGH which is a high-level voltage input to the first voltage input terminal V1 to the output terminal GOUT.

The sixth transistor T6 may be connected between the output terminal GOUT and the second voltage input terminal V2. A gate of the sixth transistor T6 may be connected to the third node Q. The sixth transistor T6 may be a pull-down transistor configured to transmit a low-level voltage to the output terminal GOUT. The sixth transistor T6 may be turned on when the voltage at the third node Q is at a low level, to transmit the second voltage VGL which is a low-level voltage input to the second voltage input terminal V2 to the output terminal GOUT.

The first capacitor C1 may be connected between the output terminal GOUT and the third node Q. The second capacitor C2 may be connected between the first voltage input terminal V1 and the second node QB. The first capacitor C1 may be configured to maintain the voltage at the third node Q, and the second capacitor C2 may be configured to maintain the voltage at the second node QB. The first capacitor C1 may be configured to change the voltage at the third node Q in response to voltage fluctuations at the output terminal GOUT. The second capacitor C2 may be omitted.

Next, referring to FIG. 4B, a silicon transistor included in the stage ST may also have a double-gate structure like the oxide transistor. In other words, each of silicon transistors included in the stage ST may have an upper gate and a lower gate. For example, the first transistor T1 may have a first upper gate electrode G1t and a first lower gate electrode G1b. The second transistor T2 may have a second upper gate electrode G2t and a second lower gate electrode G2b. The third transistor T3 may have a third upper gate electrode G3t and a third lower gate electrode G3b. The fifth transistor T5 may have a fifth upper gate electrode G5t and a fifth lower gate electrode G5b. The sixth transistor T6 may have a sixth upper gate electrode G6t and a sixth lower gate electrode G6b.

According to some embodiments, the upper gate and the lower gate of each of the silicon transistors may be electrically connected to each other. For example, the first upper gate electrode G1t and the first lower gate electrode G1b may be electrically connected to each other, the second upper gate electrode G2t and the second lower gate electrode G2b may be electrically connected to each other, and the third upper gate electrode G3t and the third lower gate electrode G3b may be electrically connected to each other. Likewise, the fifth upper gate electrode G5t and the fifth lower gate electrode G5b may be electrically connected to each other, and the sixth upper gate electrode G6t and the sixth lower gate electrode G6b may be electrically connected to each other. As described above, when the upper gate and the lower gate of each of the silicon transistors are connected to each other, electron mobility within the silicon transistors may be relatively improved.

FIG. 5 is a cross-sectional view schematically showing a portion of a non-display region of the display apparatus 1 according to some embodiments.

FIG. 5 shows a cross-section of a portion corresponding to the second transistor T2 and the fourth transistor T4 of the gate driving circuit 13 (FIG. 2) shown in FIG. 4A, and some may be omitted. A stacked structure of the first transistor T1, the third transistor T3, the fifth transistor T5, and the sixth transistor T6 may be identical or similar to the second transistor T2.

A substrate 100 may include a glass material, a ceramic material, a metal material, or a flexible or bendable material. When the substrate 100 has flexible or bendable characteristics, the substrate 100 may include a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), and cellulose acetate propionate (CAP).

The substrate 100 may have a single-layered or multilayer structure of the material, and may further include an inorganic layer when having the multilayer structure. For example, the substrate 100 may have a stacked structure of a first base layer/a barrier layer/a second base layer. Each of the first base layer and the second base layer may include a polymer resin. The first base layer and the second base layer may include a transparent polymer resin. The barrier layer prevents or reduces penetration of external substances and may be a single layer or a multilayer, each including an inorganic material such as silicon nitride (SiNₓ) or silicon oxide (SiOₓ).

A buffer layer 111 may be arranged on the substrate 100. The buffer layer 111 may increase the smoothness of the top surface of the substrate 100, and the buffer layer 111 may include an oxide film such as silicon oxide (SiOₓ), a nitride film such as silicon nitride (SiNₓ), or silicon oxynitride (SiON).

A barrier layer 110 may be further included between the substrate 100 and the buffer layer 111. The barrier layer 110 may prevent, reduce, or minimize penetration of impurities from the substrate 100, etc. into a silicon semiconductor layer. The barrier layer 110 may be a single layer or a multilayer, each including an inorganic material such as silicon nitride (SiNₓ) or silicon oxide (SiOₓ). The barrier layer 110 may include a first barrier layer 110a and a second barrier layer 110b.

As shown in FIG. 5, a lower metal layer BML may be arranged between the first barrier layer 110a and the second barrier layer 110b. The lower metal layer BML may be arranged to partially overlap a second semiconductor layer A2. At this time, the lower metal layer BML may function as a lower gate electrode of silicon transistors. For example, the lower metal layer BML may include the second lower gate electrode G2b of the second transistor T2. According to some embodiments, the lower metal layer BML may be arranged between the second barrier layer 110b and the buffer layer 111.

A plurality of transistors may be arranged on the buffer layer 111. In detail, semiconductor layers of the first transistor T1 (FIG. 4B), the second transistor T2, the third transistor T3 (FIG. 4B), the fifth transistor T5 (FIG. 4B), and the sixth transistor T6 (FIG. 4B), which are silicon transistors, may be arranged on the buffer layer 111. In other words, a silicon semiconductor layer may be arranged on the buffer layer 111. For example, the second semiconductor layer A2 of the second transistor T2 may be arranged on the buffer layer 111. The second semiconductor layer A2, which is a silicon semiconductor layer, may include a silicon-based material, for example, polycrystalline silicon.

A silicon semiconductor layer may include a channel region, a source region, and a drain region of each of the first transistor T1 (FIG. 4B), the second transistor T2, the third transistor T3 (FIG. 4B), the fifth transistor T5 (FIG. 4B), and the sixth transistor T6 (FIG. 4B). In other words, a channel region, a source region, and a drain region of each of silicon transistors may be partial regions of a silicon semiconductor layer. For example, the second semiconductor layer A2 may include a second channel region CH2, a second source region S2, and a second drain region D2 of the second transistor T2.

A first gate insulating layer 112 may be arranged above the second semiconductor layer A2. The first gate insulating layer 112 may include an inorganic material including oxide or nitride. For example, the first gate insulating layer 112 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

Upper gate electrodes of the first transistor T1 (FIG. 4B), the second transistor T2, the third transistor T3 (FIG. 4B), the fifth transistor T5 (FIG. 4B), and the sixth transistor T6 (FIG. 4B), which are silicon transistors, may be arranged on the first gate insulating layer 112. For example, the second upper gate electrode G2t of the second transistor T2 may be arranged on the first gate insulating layer 112.

The upper gate electrodes of the first transistor T1 (FIG. 4B), the second transistor T2, the third transistor T3 (FIG. 4B), the fifth transistor T5 (FIG. 4B), and the sixth transistor T6 (FIG. 4B) may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may be formed as a single layer or a multilayer, each including at least one material.

As described above, a gate of each of silicon transistors may include an upper gate electrode and a lower gate electrode. For example, a second gate G2 of the second transistor T2 may include the second upper gate electrode G2t and the second lower gate electrode G2b. According to some embodiments, the upper gate electrode and the lower gate electrode of each of the silicon transistors may be connected to each other. For example, the second upper gate electrode G2t and the second lower gate electrode G2b of the second transistor T2 may be electrically connected to each other.

The second upper gate electrode G2t and the second lower gate electrode G2b may be arranged on different layers and may be opposite to each other with the second semiconductor layer A2 therebetween. Accordingly, the second upper gate electrode G2t and the second lower gate electrode G2b may be electrically connected to each other via a second connection electrode CE2 described below. The second connection electrode CE2 may be arranged above the second upper gate electrode G2t and may be connected to each of the second upper gate electrode G2t and the second lower gate electrode G2b via a contact hole.

As shown in FIG. 5, when the second upper gate electrode G2t and the second lower gate electrode G2b are electrically connected to each other to receive a same gate signal, a change in threshold voltage of the second transistor T2 may be minimized. In other words, when an upper gate electrode and a lower gate electrode of each of silicon transistors are connected to each other, reliability of the silicon transistors may be strengthened.

A second gate insulating layer 113 may be arranged on the second upper gate electrode G2t. The second gate insulating layer 113 may include an inorganic material including oxide or nitride. For example, the second gate insulating layer 113 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

A lower gate electrode of an oxide transistor may be arranged on the second gate insulating layer 113. For example, the fourth lower gate electrode G4b of the fourth transistor T4 may be arranged on the second gate insulating layer 113. The fourth lower gate electrode G4b may overlap a fourth semiconductor layer A4 of the fourth transistor T4.

The fourth lower gate electrode G4b may be formed as a single layer or a multilayer, each including at least one material from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A first interlayer insulating layer 114 may be arranged on the fourth lower gate electrode G4b. The first interlayer insulating layer 114 may include an inorganic material including oxide or nitride. For example, the first interlayer insulating layer 114 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An oxide semiconductor layer of an oxide transistor may be arranged on the first interlayer insulating layer 114. For example, the fourth semiconductor layer A4 of the fourth transistor T4 may be arranged on the first interlayer insulating layer 114. The fourth semiconductor layer A4 may include Zn oxide, In-Zn oxide, Ga-In-Zn oxide, etc., as a Zn oxide-based material. In some embodiments, the fourth semiconductor layer A4 may include an In—Ga—Zn—O (IGZO), In—Sn—Zn—O (ITZO), or In—Ga—Sn—Zn—O (IGTZO) semiconductor containing a metal, such as indium (In), gallium (Ga), or tin (Sn), in ZnO.

The fourth semiconductor layer A4 of the fourth transistor T4 may include a fourth channel region CH4, a fourth source region S4 on one side of the fourth channel region CH4, and a fourth drain region D4 on the other side of the fourth channel region CH4. The fourth source region S4 and the fourth drain region D4 of the fourth transistor T4 may be formed by adjusting the concentration of carriers in an oxide semiconductor to make the fourth source region S4 and the fourth drain region D4 conductive. The fourth source region S4 and the fourth drain region D4 may be formed by increasing carrier concentration via plasma treatment using hydrogen (H)-based gas, fluorine (F)-based gas, or a combination thereof on the oxide semiconductor.

The fourth upper gate electrode G4t of the fourth transistor T4 may be arranged on the fourth semiconductor layer A4. The fourth upper gate electrode G4t may be arranged to overlap the fourth semiconductor layer A4 of the fourth transistor T4. The fourth upper gate electrode G4t may be formed as a single layer or a multilayer, each including at least one material from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A third gate insulating layer 115 may be arranged between the fourth semiconductor layer A4 and the fourth upper gate electrode G4t. The third gate insulating layer 115 may include an inorganic material including oxide or nitride. For example, the second gate insulating layer 113 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). According to some embodiments, the third gate insulating layer 115 may be patterned and formed to have a shape corresponding to the fourth upper gate electrode G4t, as shown in FIG. 5. According to some embodiments, the third gate insulating layer 115 may be formed on the entire surface of the substrate 100 like the first gate insulating layer 112 and the second gate insulating layer 113.

As described above, a gate of an oxide transistor may include an upper gate electrode and a lower gate electrode. For example, a fourth gate G4 of the fourth transistor T4 may include the fourth lower gate electrode G4b and the fourth upper gate electrode G4t. According to some embodiments, the upper gate electrode and the lower gate electrode of the oxide transistor may be connected to each other. For example, the fourth upper gate electrode G4t and the fourth lower gate electrode G4b of the fourth transistor T4 may be electrically connected to each other.

The fourth upper gate electrode G4t and the fourth lower gate electrode G4b may be arranged on different layers and may be opposite to each other with the fourth semiconductor layer A4 therebetween. The fourth upper gate electrode G4t and the fourth lower gate electrode G4b may be electrically connected to each other via a first connection electrode CE1 described below. The first connection electrode CE1 may be arranged above the fourth upper gate electrode G4t and may be connected to each of the fourth upper gate electrode G4t and the fourth lower gate electrode G4b via a contact hole.

As the fourth upper gate electrode G4t and the fourth lower gate electrode G4b of the fourth transistor T4 are connected to each other, a same gate signal may be applied to the fourth upper gate electrode G4t and the fourth lower gate electrode G4b. When a gate-on voltage is applied to the fourth upper gate electrode G4t, a channel may be formed above a fourth channel region C4, and when a gate-on voltage is applied to the fourth lower gate electrode G4b, a channel may be formed under the fourth channel region C4. Accordingly, when the fourth transistor T4 has a double-gate structure in which an upper gate and a lower gate are connected to each other, compared to a single-gate structure, the thickness of a channel that may be formed in the fourth channel region C4 may increase and electron mobility may be increased.

By including the structure as described above, the display apparatus according to some embodiments may minimize a change in threshold voltage of the fourth transistor T4 and relatively improve driving characteristics. In particular, in the case of oxide transistors such as the fourth transistor T4, impurities in an oxide semiconductor layer may deteriorate characteristics of a channel region, and thus, when the fourth transistor T4 is formed to have a double-gate structure in which an upper gate and a lower gate are connected to each other, reliability of the oxide transistor may be further enhanced.

A second interlayer insulating layer 116 may be arranged to cover an oxide transistor. For example, the second interlayer insulating layer 116 may cover the fourth transistor T4. The second interlayer insulating layer 116 may be arranged above the fourth upper gate electrode G4t of the fourth transistor T4. The second interlayer insulating layer 116 may include an inorganic material including oxide or nitride. For example, the second interlayer insulating layer 116 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The first connection electrode CE1, the second connection electrode CE2, and a first node connection line CN1 may be arranged on the second interlayer insulating layer 116. Each of the first connection electrode CE1, the second connection electrode CE2, and the first node connection line CN1 may be formed as a single layer or a multilayer, each including at least one material from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The first connection electrode CE1 may connect an upper gate electrode to a lower gate electrode of an oxide transistor. For example, as shown in FIG. 5, the first connection electrode CE1 may connect the fourth upper gate electrode G4t to the fourth lower gate electrode G4b. One side of the first connection electrode CE1 may be connected to the fourth upper gate electrode G4t via a contact hole penetrating the second interlayer insulating layer 116. The other side of the first connection electrode CE1 may be connected to the fourth lower gate electrode G4b via a contact hole penetrating the second interlayer insulating layer 116 and the first interlayer insulating layer 114.

The second connection electrode CE2 may connect an upper gate electrode to a lower gate electrode of a silicon transistor. For example, as shown in FIG. 5, the second connection electrode CE2 may connect the second upper gate electrode G2t to the second lower gate electrode G2b. One side of the second connection electrode CE2 may be connected to the second upper gate electrode G2t via a contact hole penetrating the second interlayer insulating layer 116, the first interlayer insulating layer 114, and the second gate insulating layer 113. The other side of the second connection electrode CE2 may be connected to the second lower gate electrode G2b via a contact hole penetrating the second interlayer insulating layer 116, the first interlayer insulating layer 114, the second gate insulating layer 113, the first gate insulating layer 112, the buffer layer 111, and the second barrier layer 110b.

The first node connection line CN1 may correspond to a node that connects the second transistor T2 to the fourth transistor T4. The first node connection line CN1 may connect a silicon semiconductor layer to an oxide semiconductor layer. For example, the first node connection line CN1 may be connected to the second source region S2 of the second semiconductor layer A2 and the fourth drain region D4 of the fourth semiconductor layer A4.

A first planarization layer 118 and a second planarization layer 119 may be arranged on the first connection electrode CE1, the second connection electrode CE2, and the first node connection line CN1. The first planarization layer 118 and the second planarization layer 119 may include an organic material such as acryl, benzocyclobutene (BCB), polyimide, or hexamethyldisiloxane (HMDSO). Alternatively, the first planarization layer 118 and the second planarization layer 119 may include an inorganic material. The first planarization layer 118 and the second planarization layer 119 serve as protective films covering a plurality of transistors, and upper surfaces of the first planarization layer 118 and the second planarization layer 119 may be planarized. The first planarization layer 118 and the second planarization layer 119 may be formed as a single layer or a multilayer. According to some embodiments, the first connection electrode CE1 and the second connection electrode CE2 may be arranged between the first planarization layer 118 and the second planarization layer 119.

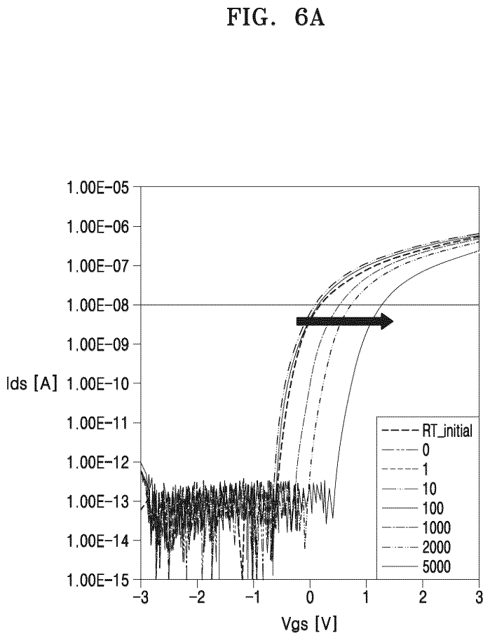

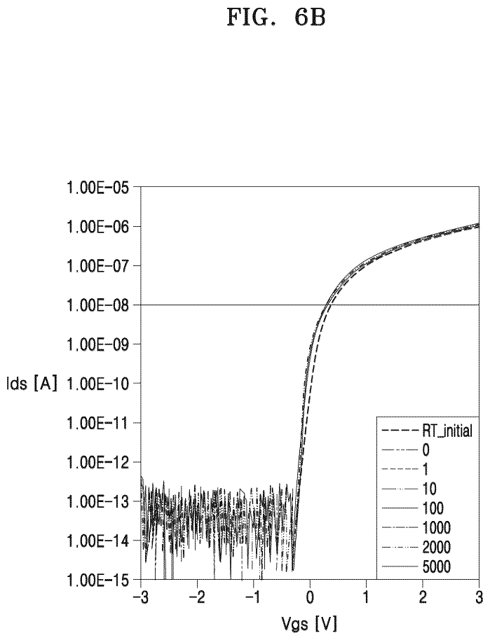

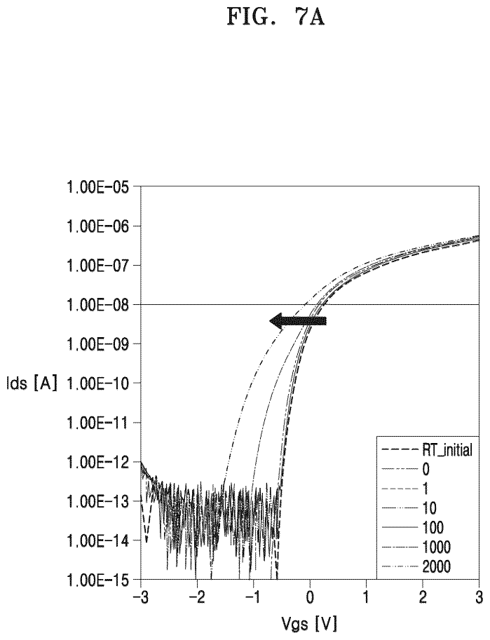

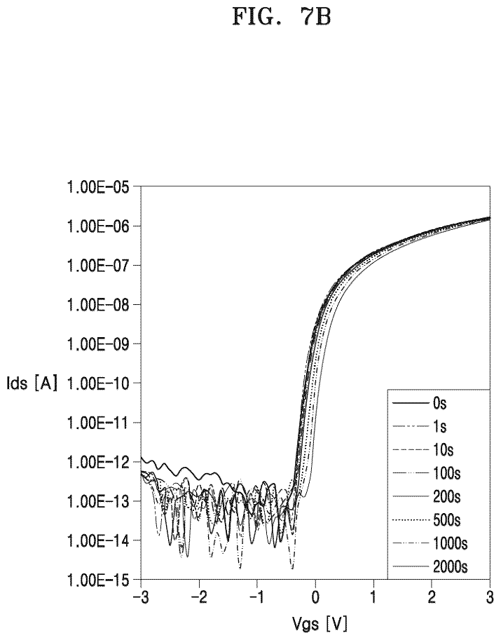

FIGS. 6A to 7B are graphs showing characteristics of an oxide transistor shown in FIG. 4A. FIGS. 6A and 6B are graphs of results of measuring negative bias temperature stress (NBTS) values of the fourth transistor T4, and FIGS. 7A and 7B are graphs of results of measuring positive bias temperature stress (PBTS) values of the fourth transistor T4.

FIGS. 6A and 7A are graphs showing voltage-current characteristics when the fourth lower gate electrode G4b (FIG. 5) of the fourth transistor T4 (FIG. 5) is connected to the fourth source region S4 (FIG. 5). FIGS. 6B and 7B are graphs showing voltage-current characteristics when the fourth lower gate electrode G4b (FIG. 5) of the fourth transistor T4 (FIG. 5) is connected to the fourth upper gate electrode G4t (FIG. 5). Referring to FIGS. 6A to 7B, the X axis represents a gate-source voltage (Vgs, [V]) of the fourth transistor T4, and the Y axis represents a current (Ids, [A]) between a source electrode and a drain electrode of the fourth transistor T4.

Referring to FIG. 6A, it may be confirmed that when 1 nA is applied to the fourth transistor T4 having the lower gate connected to the source region for 5,000seconds under conditions of a drain voltage (Vds) of −20 V and a temperature of 70° C., a threshold voltage (Vth) moves by about 1.5 V depending on stress time. In contrast, it may be confirmed that the fourth transistor T4 having the lower gate connected to the upper gate has almost no change in threshold voltage (ΔVth) depending on stress time under the same conditions, shown in FIG. 6B.

Likewise, referring to FIG. 7A, it may be confirmed that when 1 nA is applied to the fourth transistor T4 having the lower gate connected to the source region for 5,000 seconds under conditions of a drain voltage (Vds) of +20 V and a temperature of 70° C., the threshold voltage (Vth) moves by about 1 V depending on stress time. In contrast, it may be confirmed that the fourth transistor T4 having the lower gate connected to the upper gate has almost no change in threshold voltage (ΔVth) depending on stress time under the same conditions, shown in FIG. 7B.

In other words, when checking the graphs of FIGS. 6A to 7B, it may be seen that even in a case where an oxide transistor has a double-gate structure in a same way, the structure of the oxide transistor in which an upper gate and a lower gate are connected to each other has excellent effects in terms of stability of threshold voltage. In other words, in the display apparatus according to some embodiments, an oxide transistor has a double-gate structure in which an upper gate and a lower gate are connected to each other, and thus, reliability of the oxide transistor may be increased, and an output signal of a gate driving circuit may be stably generated.

FIG. 8 is an equivalent circuit diagram schematically showing a light-emitting diode of the display apparatus 1 according to some embodiments and a pixel circuit electrically connected to the light-emitting diode.

Referring to FIG. 8, one pixel PX (FIG. 3) may include a pixel circuit PC and a light-emitting device electrically connected to the pixel circuit PC. The light-emitting device may be a light-emitting diode LED having an anode (or a pixel electrode) and a cathode (or an opposite electrode).

According to some embodiments, the pixel circuit PC may include first to seventh main transistors M1 to M7, and a storage capacitor Cst. The first to seventh main transistors M1 to M7 and the storage capacitor Cst may be connected to first to fifth gate lines GWL, GCL, EML, GIL, and GBL configured to respectively transmit the first to fifth gate signals GW, GC, EM, GI, and GB, the data line DL configured to transmit the data signal DATA, a driving voltage line PL configured to transmit the driving voltage ELVDD, a first initialization voltage line VL1 configured to transmit the first initialization voltage Vint, a second initialization voltage line VL2 configured to transmit the second initialization voltage Vaint, and a common electrode to which the common voltage ELVSS is applied.

The first main transistor M1 may be a driving transistor of which the magnitude of a drain current is determined according to a gate-source voltage, and the second to seventh main transistors M2 to M7 may each be a switching transistor that is turned on/off according to a gate-source voltage, or substantially a gate voltage. The first to seventh main transistors M1 to M7 may be formed as thin-film transistors.

Some of the first to seventh main transistors M1 to M7 may each be provided as an n-channel MOSFET (NMOS), and the others may each be provided as a p-channel MOSFET (PMOS). For example, as shown in FIG. 8, among the first to seventh main transistors M1 to M7, the first main transistor M1, the second main transistor M2, and the fifth to seventh main transistors M5, M6, and M7 may each be provided as a PMOS, and the third main transistor M3 and the fourth main transistor M4 may each be provided as an NMOS. According to the type (N type or P type) and/or operating condition of a transistor, a first terminal of each of the first to seventh main transistors M1 to M7 may be a source terminal or a drain terminal, and a second terminal of each of the first to seventh main transistors M1 to M7 may be different from the first terminal. For example, when the first terminal is a source terminal, the second terminal is a drain terminal. According to some embodiments, the source terminal and the drain terminal may be interchangeably referred to as a source electrode and a drain electrode, respectively.

According to some embodiments, the first main transistor M1, the second main transistor M2, and the fifth to seventh main transistors M5, M6, and M7 may each be a silicon transistor. The silicon transistor includes a silicon semiconductor layer and may have high electron mobility and excellent reliability. For example, the first main transistor M1, which directly affects the brightness of the light-emitting diode LED, may be formed as a silicon transistor including a silicon semiconductor layer to implement a high-resolution display apparatus.

The third main transistor M3 and the fourth main transistor M4 may each be an oxide transistor. The oxide transistor includes an oxide semiconductor layer, has a low off-current, and is capable of low-frequency driving. For example, when the third main transistor M3 and the fourth main transistor M4 are used as oxide transistors, power consumption of the display apparatus may be reduced.

The first main transistor M1 may be a driving transistor. The first main transistor M1 may be connected between the driving voltage line PL and the light-emitting diode LED. The first main transistor M1 may be connected between a first node N1 and a third node N3. A gate of the first main transistor M1 may be connected to the storage capacitor Cst, the first terminal of the first main transistor M1 may be electrically connected to the driving voltage line PL via the fifth main transistor M5, and the second terminal of the first main transistor M1 may be electrically connected to the pixel electrode (for example, an anode) of the light-emitting diode LED via the sixth main transistor M6. The first main transistor M1 may be configured to supply a driving current I_{d} to the light-emitting diode LED according to a switching operation of the second main transistor M2.

The second main transistor M2 may be a data write transistor. The second main transistor M2 may be connected between the data line DL and the first node N1. A gate of the second main transistor M2 may be connected to the first gate line GWL, the first terminal of the second main transistor M2 may be connected to the data line DL, and the second terminal of the second main transistor M2 may be connected to the first terminal of the first main transistor M1. The second main transistor M2 may be turned on according to the first gate signal GW received via the first gate line GWL to perform a switching operation to transmit, to the first terminal of the first main transistor M1, the data signal DATA transmitted to the data line DL.

The third main transistor M3 may be a compensation transistor configured to compensate for a threshold voltage of the first main transistor M1. The third main transistor M3 may be connected between a second node N2 and the third node N3. A gate of the third main transistor M3 may include a third upper gate electrode G3t′ and a third lower gate electrode G3b′. The third upper gate electrode G3t′ of the third main transistor M3 may be connected to the second gate line GCL. The third lower gate electrode G3b′ of the third main transistor M3 may be connected to the third upper gate electrode G3t′. The first terminal of the third main transistor M3 may be connected to the storage capacitor Cst and the gate of the first main transistor M1. The first terminal of the third main transistor M3 may be connected to the fourth main transistor M4. The second terminal of the third main transistor M3 may be connected to the second terminal of the first main transistor M1 and may be electrically connected to the light-emitting diode LED via the sixth main transistor M6. The third main transistor M3 may be turned on according to the second gate signal GC received via the second gate line GCL to electrically connect the gate of the first main transistor M1 to the second terminal of the first main transistor M1 to diode-connect the first main transistor M1.

The fourth main transistor M4 may be a first initialization transistor configured to initialize the gate of the first main transistor M1. The fourth main transistor M4 may be connected between the second node N2 and the first initialization voltage line VL1. A gate of the fourth main transistor M4 may include a fourth upper gate electrode G4t′ and a fourth lower gate electrode G4b′. The fourth upper gate electrode G4t′ of the fourth main transistor M4 may be connected to the fourth gate line GIL. The fourth lower gate electrode G4b′ of the fourth main transistor M4 may be connected to the fourth upper gate electrode G4t′. The first terminal of the fourth main transistor M4 may be connected to the first initialization voltage line VL1. The second terminal of the fourth main transistor M4 may be connected to the storage capacitor Cst, the first terminal of the third main transistor M3, and the gate of the first main transistor M1. The fourth main transistor M4 may be turned on according to the fourth gate signal GI received via the fourth gate line GIL to transmit the first initialization voltage Vint to the gate of the first main transistor M1, and may be configured to perform an initialization operation to initialize a voltage of the gate of the first main transistor M1.

According to some embodiments, the third lower gate electrode G3b′ of the third main transistor M3 may be electrically connected to the third upper gate electrode G3t′, and the fourth lower gate electrode G4b′ of the fourth main transistor M4 may be electrically connected to the fourth upper gate electrode G4t′. In other words, in the gate driving circuit 13 (FIG. 2) as well as in the pixel circuit of the display region DA (FIG. 1), an oxide transistor may have a double-gate structure in which an upper gate and a lower gate are connected to each other. When a gate-on voltage is applied to a lower gate electrode and an upper gate electrode of the oxide transistor, a voltage difference between the lower gate and the upper gate may be eliminated and electron mobility may be relatively improved. Accordingly, the third main transistor M3 and the fourth main transistor M4, which are oxide transistors, may have relatively improved driving characteristics and relatively improved reliability.

The fifth main transistor M5 may be an operation control transistor. The fifth main transistor M5 may be connected between the driving voltage line PL and the first node N1. A gate of the fifth main transistor M5 may be connected to the third gate line EML and may be configured to receive the third gate signal EM. The third gate signal EM may be an emission control signal, and the third gate line EML may be an emission control line. The first terminal of the fifth main transistor M5 may be connected to the driving voltage line PL, and the second terminal of the fifth main transistor M5 may be connected to the first terminal of the first main transistor M1 and the second terminal of the second main transistor M2.

The sixth main transistor M6 may be an emission control transistor. The sixth main transistor M6 may be connected between the third node N3 and the light-emitting diode LED. A gate of the sixth main transistor M6 may be connected to the third gate line EML and may be configured to receive the third gate signal EM. The first terminal of the sixth main transistor M6 may be connected to the second terminal of the first main transistor M1 and the second terminal of the third main transistor M3. The second terminal of the sixth main transistor M6 may be electrically connected to the second terminal of the seventh main transistor M7 and the pixel electrode (for example, an anode) of the light-emitting diode LED.

The fifth main transistor M5 and the sixth main transistor M6 may be simultaneously turned on according to the third gate signal EM received via the third gate line EML, such that the driving voltage ELVDD may be transmitted to the light-emitting diode LED, thereby allowing the driving current la to flow through the light-emitting diode LED.

The seventh main transistor M7 may be a second initialization transistor configured to initialize the pixel electrode (for example, an anode) of the light-emitting diode LED. The seventh main transistor M7 may be connected between the second initialization voltage line VL2 and the light-emitting diode LED. A gate of the seventh main transistor M7 may be connected to the fifth gate line GBL. The first terminal of the seventh main transistor M7 may be connected to the second initialization voltage line VL2. The second terminal of the seventh main transistor M7 may be connected to the second terminal of the sixth main transistor M6 and the pixel electrode (for example, an anode) of the light-emitting diode LED. The seventh main transistor M7 may be turned on according to the fifth gate signal GB received via the fifth gate line GBL to transmit the second initialization voltage Vaint to the pixel electrode (for example, an anode) of the light-emitting diode LED and initialize the pixel electrode of the light-emitting diode LED.

The fifth gate signal GB may be substantially synchronized with the first gate signal GW. In some embodiments, the fifth gate signal GB may be substantially synchronized with the first gate signal GW of a pixel located in the next row. For example, the fifth gate line GBL may be substantially the same as the first gate line GWL of a pixel located in the next row.

The storage capacitor Cst may include a first capacitor electrode connected to the gate of the first main transistor M1 and a second capacitor electrode connected to the driving voltage line PL. The storage capacitor Cst may be configured to store and maintain a voltage corresponding to a voltage difference between the driving voltage line PL and the gate of the first main transistor M1, thereby maintaining a voltage applied to the gate of the first main transistor M1. In some embodiments, the first capacitor electrode of the storage capacitor Cst and the gate of the first main transistor M1 may be integrally provided as a single body.

The light-emitting diode LED may receive a driving current from the first main transistor M1 and emit light, thereby displaying an image. The light-emitting diode LED may include a pixel electrode and an opposite electrode. The pixel electrode of the light-emitting diode LED may be electrically connected to the first main transistor M1 via the sixth main transistor M6. The opposite electrode of the light-emitting diode LED may be electrically connected to a common voltage line VSSL and may receive a voltage corresponding to the common voltage ELVSS via the common voltage line VSSL.

FIG. 8 shows that the pixel circuit PC includes seven transistors and one capacitor, but the disclosure is not limited thereto. The number of transistors and capacitors included in the pixel circuit PC and a circuit design may vary.

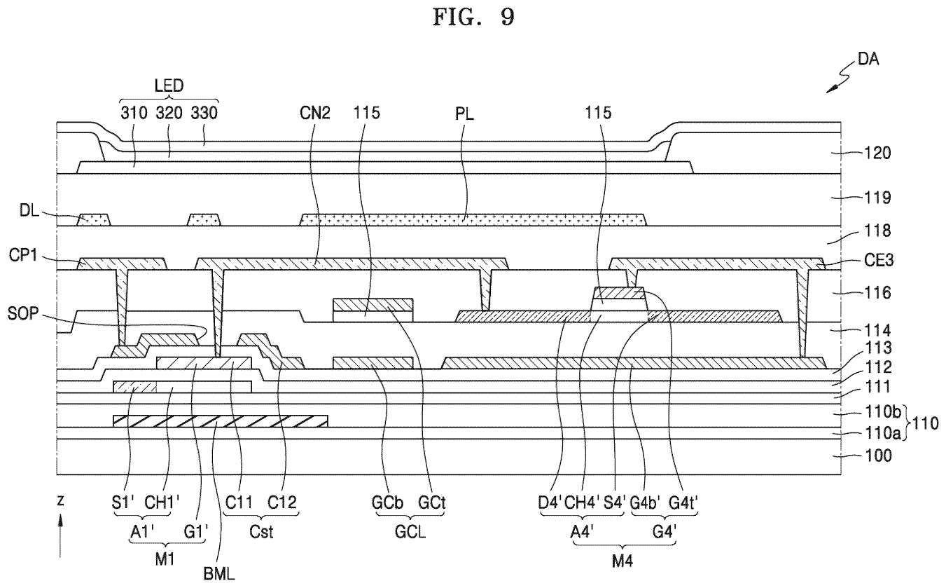

FIG. 9 is a cross-sectional view schematically showing a portion of a display region of the display apparatus 1 according to some embodiments. The same reference numerals for the components of FIG. 9 are substituted for those previously described with reference to FIG. 5.

FIG. 9 shows a cross-section of a portion corresponding to the first main transistor M1 and the fourth main transistor M4 of the pixel circuit PC shown in FIG. 8, and some may be omitted. A stacked structure of the second main transistor M2, the fifth main transistor M5, the sixth main transistor M6, and the seventh main transistor M7 may be identical or similar to the first main transistor M1, and a stacked structure of the third main transistor M3 may be identical or similar to the fourth main transistor M4.

As shown in FIG. 9, the lower metal layer BML may be arranged between the first barrier layer 110a and the second barrier layer 110b. The lower metal layer BML may be arranged to overlap a first semiconductor layer A1′ in correspondence with the first main transistor M1. The buffer layer 111 may be arranged on the lower metal layer BML.

A plurality of main transistors may be arranged on the buffer layer 111. In detail, semiconductor layers of the first main transistor M1, the second main transistor M2 (FIG. 8), and the fifth to seventh main transistors M5, M6, and M7 (FIG. 8), which are silicon transistors, may be arranged on the buffer layer 111. In other words, a silicon semiconductor layer may be arranged on the buffer layer 111. For example, the first semiconductor layer A1′ of the first main transistor M1 may be arranged on the buffer layer 111. The first semiconductor layer A1′, which is a silicon semiconductor layer, may include a silicon-based material, for example, polycrystalline silicon.

The first gate insulating layer 112 may be arranged above the first semiconductor layer A1′, and gate electrodes of silicon transistors may be arranged on the first gate insulating layer 112. For example, a first gate electrode G1′ of the first main transistor M1, a second gate electrode of the second main transistor M2 (FIG. 8), a fifth gate electrode of the fifth main transistor M5 (FIG. 8), a sixth gate electrode of the sixth main transistor M6 (FIG. 8), and a seventh gate electrode of the seventh main transistor M7 (FIG. 8) may be arranged on the first gate insulating layer 112. In addition, the first gate electrode G1′ of the first main transistor M1 may function as a first capacitor electrode C11 of the storage capacitor Cst.

The first gate electrode G1′ may be formed as a single layer or a multilayer, each including at least one material from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The gate electrodes of the second main transistor M2 (FIG. 8) and the fifth to seventh main transistors M5, M6, and M7 (FIG. 8) may include the same material as the first gate electrode G1′.

The second gate insulating layer 113 may be arranged on the first gate electrode G1′, and a second capacitor electrode C12 of the storage capacitor Cst may be arranged on the second gate insulating layer 113. The second capacitor electrode C12 may be arranged to overlap the first capacitor electrode C11. The second capacitor electrode C12 may include an opening SOP. The opening SOP is formed by removing a portion of the second capacitor electrode C12, and may have a closed shape. The second gate insulating layer 113 may serve as a dielectric layer of the storage capacitor Cst.

The second capacitor electrode C12 of the storage capacitor Cst may be formed as a single layer or a multilayer, each including at least one material from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A lower gate line GCb of the second gate line GCL and the fourth lower gate electrode G4b′ of the fourth main transistor M4 may be arranged on the second gate insulating layer 113. The lower gate line GCb of the second gate line GCL and the fourth lower gate electrode G4b′ may include the same material as the second capacitor electrode C12. The lower gate line GCb of the second gate line GCL may extend in one direction and may include the third lower gate electrode G3b′ (FIG. 8) of the third main transistor M3 (FIG. 8). The fourth lower gate electrode G4b′ may overlap a fourth semiconductor layer A4′ of the fourth main transistor M4.

The first interlayer insulating layer 114 may be arranged on the second capacitor electrode C12, the lower gate line GCb, and the fourth lower gate electrode G4b′. The fourth semiconductor layer A4′ of the fourth main transistor M4 may be arranged on the first interlayer insulating layer 114. The fourth semiconductor layer A4′ may include an oxide semiconductor. For example, the fourth semiconductor layer A4′ may include Zn oxide, In-Zn oxide, Ga—In—Zn oxide, etc., as a Zn oxide-based material. In some embodiments, the fourth semiconductor layer A4′ may include an In—Ga—Zn—O (IGZO), In—Sn—Zn—O (ITZO), or In—Ga—Sn—Zn—O (IGTZO) semiconductor containing a metal, such as indium (In), gallium (Ga), or tin (Sn), in ZnO. The fourth semiconductor layer A4′ may include a fourth channel region CH4′, a fourth source region S4′ on one side of the fourth channel region CH4′, and a fourth drain region D4′ on the other side of the fourth channel region CH4′.

The fourth upper gate electrode G4t′ of the fourth main transistor M4 may be arranged on the fourth semiconductor layer A4′. The fourth upper gate electrode G4t′ may be arranged to overlap the fourth semiconductor layer A4′ of the fourth main transistor M4. The fourth upper gate electrode G4t′ may be formed as a single layer or a multilayer, each including at least one material from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An upper gate line GCt of the second gate line GCL may be arranged on the first interlayer insulating layer 114. The upper gate line GCt and the fourth upper gate electrode G4t′ may be arranged on a same layer and may include a same material. The upper gate line GCt may be arranged to overlap the lower gate line GCb. The upper gate line GCt of the second gate line GCL may extend in one direction and may include the third upper gate electrode G3t′ (FIG. 8) of the third main transistor M3 (FIG. 8).

The third gate insulating layer 115 may be arranged between the fourth semiconductor layer A4′ and the fourth upper gate electrode G4t′. According to some embodiments, the third gate insulating layer 115 may be patterned and formed to have a shape corresponding to the fourth upper gate electrode G4t′ and the upper gate line GCt, as shown in FIG. 9. According to some embodiments, the third gate insulating layer 115 may be formed on the entire surface of the substrate 100 like the first gate insulating layer 112 and the second gate insulating layer 113.

According to some embodiments, a gate of an oxide transistor may include an upper gate electrode and a lower gate electrode, and the upper gate electrode and the lower gate electrode of the oxide transistor may be connected to each other. For example, the third lower gate electrode G3b′ and the third upper gate electrode G3t′ of the third main transistor M3 may be electrically connected to each other, and the fourth lower gate electrode G4b′ and the fourth upper gate electrode G4t′ of the fourth main transistor M4 may be electrically connected to each other.

The fourth upper gate electrode G4t′ and the fourth lower gate electrode G4b′ may be arranged on different layers and may be opposite to each other with the fourth semiconductor layer A4′ therebetween. The fourth upper gate electrode G4t′ and the fourth lower gate electrode G4b′ may be electrically connected to each other via a third connection electrode CE3 described below. The third connection electrode CE3 may be arranged above the fourth upper gate electrode G4t′ and may be connected to each of the fourth upper gate electrode G4t′ and the fourth lower gate electrode G4b′ via a contact hole. The third upper gate electrode G3t′ and the third lower gate electrode G3b′ may also be electrically connected to each other via a connection electrode.

When each of the third main transistor M3 (FIG. 8) and the fourth main transistor M4 has a double-gate structure in which an upper gate and a lower gate are connected to each other, compared to a single-gate structure, the thickness of a channel that may be formed in a channel region may increase and electron mobility may be increased. In addition, a voltage difference between the upper gate and the lower gate is eliminated, and thus, device stabilization may be achieved. Accordingly, by including the structure as described above, the display apparatus according to some embodiments may minimize a change in threshold voltage of an oxide transistor and relatively improve driving characteristics and reliability.

The second interlayer insulating layer 116 may be arranged to cover the fourth main transistor M4. A first connection pattern CP1, a second node connection line CN2, and the third connection electrode CE3 may be arranged on the second interlayer insulating layer 116. Each of the first connection pattern CP1, the second node connection line CN2, and the third connection electrode CE3 may be formed as a single layer or a multilayer, each including at least one material from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The third connection electrode CE3 may connect an upper gate electrode to a lower gate electrode of an oxide transistor in the display region DA. For example, the third connection electrode CE3 may connect the fourth upper gate electrode G4t′ to the fourth lower gate electrode G4b′, as shown in FIG. 9. One side of the third connection electrode CE3 may be connected to the fourth upper gate electrode G4t′ via a contact hole penetrating the second interlayer insulating layer 116. The other side of the third connection electrode CE3 may be connected to the fourth lower gate electrode G4b′ via a contact hole penetrating the second interlayer insulating layer 116 and the first interlayer insulating layer 114.

The second node connection line CN2 may connect the first gate electrode G1′ of the first main transistor M1 to the fourth semiconductor layer A4′ of the fourth main transistor M4. One end of the second node connection line CN2 may be connected to the first gate electrode G1′ via a contact hole penetrating the first interlayer insulating layer 114 and the second interlayer insulating layer 116, and the other end of the second node connection line CN2 may be connected to the fourth drain region D4′ of the fourth semiconductor layer A4′ via a contact hole penetrating the second interlayer insulating layer 116. The first connection pattern CP1 may be connected to the second capacitor electrode C12 of the storage capacitor Cst via a contact hole formed in the first interlayer insulating layer 114 and the second interlayer insulating layer 116. According to some embodiments, the first connection pattern CP1 may be connected to a drain region of the fifth main transistor M5 (FIG. 8).

The first planarization layer 118 may be arranged on the first connection pattern CP1, the second node connection line CN2, and the third connection electrode CE3. The data line DL and the driving voltage line PL may be arranged on the first planarization layer 118. According to some embodiments, the data line DL may be connected to a connection pattern via a contact hole formed in the first planarization layer 118 and thus may be electrically connected to the second main transistor M2 (FIG. 8). Likewise, the driving voltage line PL may be connected to the first connection pattern CP1 via a contact hole formed in the first planarization layer 118 and thus may be electrically connected to the storage capacitor Cst. The second planarization layer 119 may be arranged above the data line DL and the driving voltage line PL.

A bank layer 120 may be arranged above the second planarization layer 119. The bank layer 120 may define a pixel by having an opening corresponding to each pixel, that is, an opening through which a portion of a pixel electrode 310 is exposed. In addition, the bank layer 120 may prevent or reduce instances of an arc, etc. from occurring on an edge of the pixel electrode 310 by increasing a distance between the edge of the pixel electrode 310 and an opposite electrode 330 over the pixel electrode 310. The bank layer 120 may include, for example, an organic material such as polyimide or HMDSO.

The light-emitting diode LED may be arranged above the second planarization layer 119. The light-emitting diode LED may include the pixel electrode 310, an intermediate layer 320, and the opposite electrode 330. The pixel electrode 310 may include a reflective film including silver (Ag), magnesium (Mg), aluminum (Al), platinum (Pt), palladium (Pd), gold (Au), nickel (Ni), neodymium (Nd), iridium (Ir), chromium (Cr) or a compound thereof. According to some embodiments, the pixel electrode 310 may further include a conductive oxide layer above and/or under the reflective film. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to some embodiments, the pixel electrode 310 may have a three-layer structure of an ITO layer/an Ag layer/an ITO layer.

The intermediate layer 320 may include an emission layer. The emission layer may include a polymer or low-molecular weight organic material that emits light of a certain color. The emission layer may include a material that emits red light, green light, or blue light according to the light-emitting diode LED. The intermediate layer 320 may further include a functional layer under and/or above the emission layer. For example, a first functional layer may be further included between the pixel electrode 310 and the emission layer, and a second functional layer may be further included between the emission layer and the opposite electrode 330 described below. The first functional layer may include a hole transport layer and/or a hole injection layer. The second functional layer may include an electron transport layer and/or an electron injection layer.

The opposite electrode 330 may include a conductive material having a low work function. For example, the opposite electrode 330 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 330 may further include a layer including ITO, IZO, ZnO, or In₂O₃ on the (semi)transparent layer including the above-described material.

Unlike pixel electrodes 310, which are individually formed to respectively correspond to light-emitting diodes LED, the opposite electrode 330 may extend to correspond to the pixel electrodes 310. For example, a pixel electrode 310 of any one light-emitting diode LED may be separated and spaced apart from a pixel electrode 310 of another opposite electrode 330, but the opposite electrode 330 overlapping the pixel electrodes 310 may extend to cover the pixel electrodes 310.

The light-emitting diodes LED may be easily damaged by moisture or oxygen from the outside, and thus, a thin-film encapsulation layer or a sealing substrate may be arranged above the light-emitting diodes LED to cover and protect the light-emitting diodes LED. The thin-film encapsulation layer may cover the display region DA and extend to the outside of the display region DA. The thin-film encapsulation layer may include an inorganic encapsulation layer including at least one inorganic material and an organic encapsulation layer including at least one organic material. In some embodiments, the thin-film encapsulation layer may have a structure of a stack of a first inorganic encapsulation layer/an organic encapsulation layer/a second inorganic encapsulation layer. The sealing substrate may be arranged to face the substrate 100 and may be bonded to the substrate 100 in the non-display region NDA (FIG. 1) using a sealing member such as a sealant or frit.

FIG. 10 is an equivalent circuit diagram schematically showing a light-emitting diode of the display apparatus 1 according to some embodiments and a pixel circuit electrically connected to the light-emitting diode. Although FIG. 10 illustrates various components in a pixel circuit according to some embodiments, embodiments according to the present disclosure are not limited thereto, and according to various embodiments, the pixel circuit may include additional components or fewer components without departing from the spirit and scope of embodiments according to the present disclosure.

Referring to FIG. 10, the pixel circuit PC may be electrically connected to the first gate line GWL configured to transmit the first gate signal GW, a second gate line GRL configured to transmit the second gate signal GR, the third gate line EML configured to transmit the third gate signal EM, the fourth gate line GIL configured to transmit the fourth gate signal GI, a fifth gate line EMBL configured to transmit the fifth gate signal EMB, and the data line DL configured to transmit the data signal DATA. Light emission of the light-emitting diode LED may be controlled by the third gate signal EM and the fifth gate signal EMB, and thus, the third gate signal EM and the fifth gate signal EMB may represent emission control signals, and the third gate line EML and the fifth gate line EMBL may represent emission control lines. The pixel circuit PC may be electrically connected to the driving voltage line PL configured to transmit the driving voltage ELVDD, a reference voltage line VRL configured to transmit the reference voltage Vref, and an initialization voltage line VIL configured to transmit an initialization voltage Vint.

Some of the first to sixth main transistors M1 to M6 may each be provided as an NMOS, and the others may each be provided as a PMOS. For example, as shown in FIG. 10, among the first to sixth main transistors M1 to M6, the fifth main transistor M5 and the sixth main transistor M6 may each be provided as a PMOS, and the first to fourth main transistors M1 to M4 may each be provided as an NMOS. According to the type (N type or P type) and/or operating condition of a transistor, a first terminal of each of the first to sixth main transistors M1 to M6 may be a source terminal or a drain terminal, and a second terminal of each of the first to sixth main transistors M1 to M6 may be different from the first terminal. For example, when the first terminal is a source terminal, the second terminal is a drain terminal. According to some embodiments, the source terminal and the drain terminal may be interchangeably referred to as a source electrode and a drain electrode, respectively.

According to some embodiments, each of the fifth main transistor M5 and the sixth main transistor M6 may be a silicon transistor. The silicon transistor includes a silicon semiconductor layer and may have high electron mobility and excellent reliability. For example, the silicon semiconductor layer may include an inorganic semiconductor (for example, amorphous silicon or polysilicon) or an organic semiconductor.

Each of the first to fourth main transistors M1, M2, M3, and M4 may be an oxide transistor. The oxide transistor includes an oxide semiconductor layer, has a low off-current, and is capable of low-frequency driving. For example, when each of the first to fourth main transistors M1, M2, M3, and M4 is used as an oxide transistor, power consumption of the display apparatus may be reduced.

The pixel circuit PC may include the first to sixth main transistors M1, M2, M3, M4, M5, and M6, the storage capacitor Cst, a holding capacitor Chd, and an auxiliary capacitor Ca. The first main transistor M1 may be a driving transistor configured to output a driving current corresponding to the data signal DATA, and the second to sixth main transistors M2, M3, M4, M5, and M6 may be switching transistors configured to transmit a signal.

The first main transistor M1 may be connected to the driving voltage line PL and the light-emitting diode LED. The first main transistor M1 may be connected between the fifth main transistor M5 and the sixth main transistor M6. A first gate of the first main transistor M1 may include a first upper gate electrode G1t″ and a first lower gate electrode G1b″. The first upper gate electrode G1t″ may be connected to the second terminal of the second main transistor M2, the first terminal of the third main transistor M3, and the storage capacitor Cst. The first lower gate electrode G1b″ of the first main transistor M1 may be connected to the first terminal of the sixth main transistor M6, the storage capacitor Cst, and the holding capacitor Chd. The first main transistor M1 includes the first lower gate electrode G1b″, and the first lower gate electrode G1b″ is maintained at a constant voltage by the holding capacitor Chd, and thus, driving characteristics of the first main transistor M1 may be relatively improved.

The first terminal of the first main transistor M1 may be connected to the driving voltage line PL via the fifth main transistor M5, and the second terminal of the first main transistor M1 may be connected to the pixel electrode of the light-emitting diode LED via the sixth main transistor M6. The first terminal of the first main transistor M1 may be connected to the second terminal of the fifth main transistor M5. The second terminal of the first main transistor M1 may be connected to the first terminal of the sixth main transistor M6, the storage capacitor Cst, and the holding capacitor Chd. The first main transistor M1 may be configured to receive the data signal DATA according to a switching operation of the second main transistor M2 and control the amount of current flowing to the light-emitting diode LED.

The second main transistor M2 may be connected to the data line DL and a gate of the first main transistor M1. A gate of the second main transistor M2 may include a second upper gate electrode G2t″ and a second lower gate electrode G2b″. The second upper gate electrode G2t″ of the second main transistor M2 may be connected to the first gate line GWL, and the second lower gate electrode G2b″ may be connected to the second upper gate electrode G2t″. The second main transistor M2 may include the first terminal connected to the data line DL and the second terminal connected to the first node N1. The second terminal of the second main transistor M2 may be connected to an upper gate of the first main transistor M1, the first terminal of the third main transistor M3, and the storage capacitor Cst. The second main transistor M2 may be turned on by the first gate signal GW transmitted to the first gate line GWL to electrically connect the data line DL to the first node N1 and transmit, to the first node N1, the data signal DATA transmitted to the data line DL.

The third main transistor M3 may be connected to the upper gate of the first main transistor M1 and the reference voltage line VRL. A gate of the third main transistor M3 may include a third upper gate electrode G3t″ and a third lower gate electrode G3b″. The third upper gate electrode G3t″ may be connected to the second gate line GRL, and the third lower gate electrode G3b″ may be connected to the third upper gate electrode G3t″. The third main transistor M3 may include the first terminal connected to the first node N1 and the second terminal connected to the reference voltage line VRL. The first terminal of the third main transistor M3 may be connected to the upper gate of the first main transistor M1, the second terminal of the second main transistor M2, and the storage capacitor Cst. The third main transistor M3 may be turned on by the second gate signal GR transmitted to the second gate line GRL to transmit, to the first node N1, the reference voltage Vref transmitted to the reference voltage line VRL.

The fourth main transistor M4 may be connected to the sixth main transistor M6 and the initialization voltage line VIL. The fourth main transistor M4 may be connected between the light-emitting diode LED and the initialization voltage line VIL. A gate of the fourth main transistor M4 may include a fourth upper gate electrode G4t″ and a fourth lower gate electrode G4b″. The fourth upper gate electrode G4t″ may be connected to the fourth gate line GIL, and the fourth lower gate electrode G4b″ may be connected to the fourth upper gate electrode G4t″. The fourth main transistor M4 may include the first terminal connected to the third node N3 and the second terminal connected to the initialization voltage line VIL. The first terminal of the fourth main transistor M4 may be connected to the second terminal of the sixth main transistor M6 and the pixel electrode of the light-emitting diode LED. The fourth main transistor M4 may be turned on by the fourth gate signal GI transmitted to the fourth gate line GIL to transmit, to the third node N3, the initialization voltage Vint transmitted to the initialization voltage line VIL and initialize the pixel electrode (for example, an anode) of the light-emitting diode LED.

According to some embodiments, an upper gate and a lower gate of an oxide transistor may be electrically connected to each other. For example, as shown in FIG. 10, at least one of the first to fourth main transistors M1, M2, M3, or M4 may have an upper gate electrode and a lower gate electrode, which are electrically connected to each other. In other words, in the gate driving circuit 13 (FIG. 2) as well as in the pixel circuit of the display region DA (FIG. 1), an oxide transistor may have a double-gate structure in which an upper gate and a lower gate are connected to each other. In FIG. 10, the first lower gate electrode G1b″ of the first main transistor M1 may be connected to the second terminal of the first main transistor M1 and the holding capacitor Chd, but in some embodiments, the first lower gate electrode G1b″ may also be connected to the first upper gate electrode G1t″.

When a gate-on voltage is applied to a lower gate electrode and an upper gate electrode of the oxide transistor, a voltage difference between the lower gate and the upper gate may be eliminated and electron mobility may be relatively improved. Accordingly, driving characteristics and reliability of the first to fourth main transistors M1, M2, M3, and M4, which are oxide transistors, may be relatively improved.

The fifth main transistor M5 may be connected to the driving voltage line PL and the first main transistor M1. The fifth main transistor M5 may include a gate connected to the third gate line EML, the first terminal connected to the driving voltage line PL, and the second terminal connected to the first terminal of the first main transistor M1. The fifth main transistor M5 may be turned on or turned off according to the third gate signal EM transmitted to the third gate line EML.

The sixth main transistor M6 may be connected to the first main transistor M1 and the light-emitting diode LED. The sixth main transistor M6 may be connected between the second node N2 and the third node N3. The sixth main transistor M6 may include a gate connected to the fifth gate line EMBL, the first terminal connected to the second node N2, and the second terminal connected to the third node N3. The first terminal of the sixth main transistor M6 may be connected to the second terminal of the first main transistor M1, the storage capacitor Cst, and the holding capacitor Chd. The second terminal of the sixth main transistor M6 may be connected to the first terminal of the fourth main transistor M4 and the pixel electrode of the light-emitting diode LED. The sixth main transistor M6 may be turned on or turned off according to the fifth gate signal EMB transmitted to the fifth gate line EMBL.

The storage capacitor Cst may be connected between the first upper gate electrode G1t″ of the first main transistor M1 and the second terminal of the first main transistor M1. A first capacitor electrode of the storage capacitor Cst may be connected to the first node N1, and a second capacitor electrode of the storage capacitor Cst may be connected to the second node N2. The first capacitor electrode of the storage capacitor Cst may be connected to the upper gate of the first main transistor M1, the second terminal of the second main transistor M2, and the first terminal of the third main transistor M3. The second capacitor electrode of the storage capacitor Cst may be connected to the second terminal of the first main transistor M1, the second lower gate electrode G2b″, the holding capacitor Chd, and the first terminal of the sixth main transistor M6. The storage capacitor Cst may be configured to store a threshold voltage of the first main transistor M1 and a voltage corresponding to the data signal DATA.

When the third main transistor M3 and the fifth main transistor M5 are turned on, the first main transistor M1 may be turned on. When a voltage of the second terminal of the first main transistor M1 decreases to a difference (Vref−Vth1) between the reference voltage Vref and a threshold voltage Vth1 of the first main transistor M1, the first main transistor M1 may be turned off, and a voltage corresponding to the threshold voltage Vth1 of the first main transistor M1 may be stored in the storage capacitor Cst to compensate for the threshold voltage Vth1 of the first main transistor M1.

The holding capacitor Chd may be connected between the driving voltage line PL and the second node N2. A first capacitor electrode of the holding capacitor Chd may be connected to the driving voltage line PL. A second capacitor electrode of the holding capacitor Chd may be connected to the second terminal of the first main transistor M1, the first lower gate electrode G1b″, the storage capacitor Cst, and the first terminal of the sixth main transistor M6. The capacitance of each of the storage capacitor Cst and the holding capacitor Chd may vary depending on the color of light emitted from the light-emitting diode LED.

The auxiliary capacitor Ca may be electrically connected to the sixth main transistor M6, the common voltage line VSSL, and the pixel electrode of the light-emitting diode LED. The auxiliary capacitor Ca may be configured to store and maintain a voltage corresponding to a voltage difference between the pixel electrode of the light-emitting diode LED and the common voltage line VSSL, thereby preventing or reducing a problem in which black luminance increases when the sixth main transistor M6 is turned off.

The light-emitting diode LED may be connected to the first main transistor M1 via the sixth main transistor M6. The light-emitting diode LED may include the pixel electrode (anode) connected to the third node N3 and the opposite electrode (cathode) facing the pixel electrode, and the opposite electrode may receive the common voltage ELVSS. According to some embodiments, the opposite electrode may be electrically connected to the common voltage line VSSL configured to provide the common voltage ELVSS by extending into the display region. Due to the fifth main transistor M5 that is turned on and the sixth main transistor M6 that is turned on, a driving current output from the first main transistor M1 flows through the light-emitting diode LED, and the light-emitting diode LED may emit light with a luminance corresponding to the magnitude of the driving current.

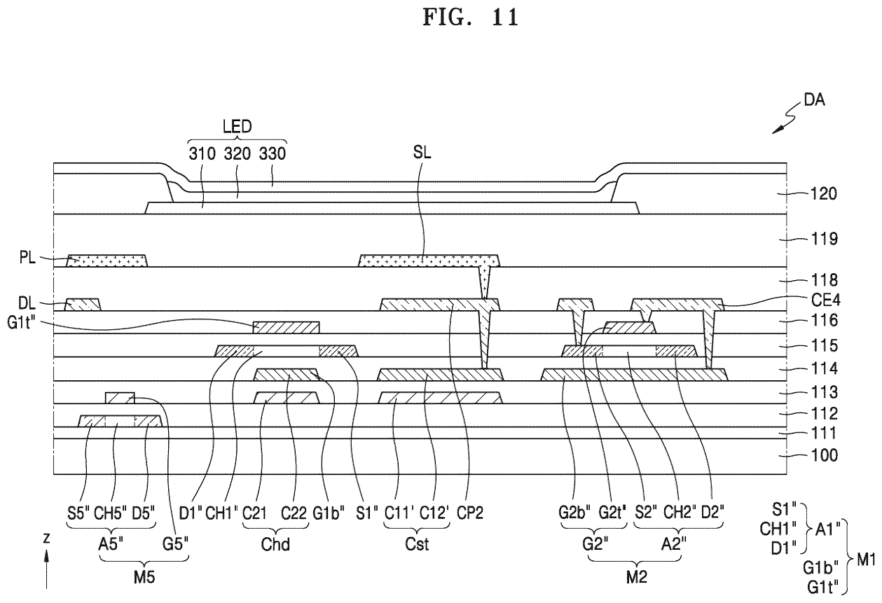

FIG. 11 is a cross-sectional view schematically showing a portion of a display region of the display apparatus 1 according to some embodiments. The same reference numerals for the components of FIG. 11 are substituted for those previously described with reference to FIGS. 5 and 9.

Referring to FIG. 11, the display apparatus 1 includes the light-emitting diode LED arranged in the display region DA. The light-emitting diode LED is arranged on the substrate 100, and the pixel circuit PC (FIG. 10) may be arranged between the substrate 100 and the light-emitting diode LED. According to some embodiments, FIG. 11 shows, as some components of the pixel circuit PC (FIG. 10), the first main transistor M1, the second main transistor M2, the fifth main transistor M5, the storage capacitor Cst, and the holding capacitor Chd.

The fifth main transistor M5 may be arranged on the buffer layer 111. The fifth main transistor M5 may include a fifth semiconductor layer A5″ including a channel region CH5″, a source region S5″ and a drain region D5″ respectively arranged on both sides of the channel region CH5″, and a fifth gate electrode G5″ overlapping the channel region CH5″. The fifth semiconductor layer A5″ may include amorphous silicon or polysilicon, and the source region S5″ and the drain region D5″ may be regions doped with impurities. The fifth gate electrode G5″ may include molybdenum (Mo), aluminum (Ai), copper (Cu), titanium (Ti), etc. and may include a single-layer or multilayer structure including the above-described material. The first gate insulating layer 112 may be arranged between the fifth gate electrode G5″ and the fifth semiconductor layer A5″.

A first capacitor electrode C11′ of the storage capacitor Cst and a first capacitor electrode C21 of the holding capacitor Chd may be arranged on the first gate insulating layer 112. The first capacitor electrode C11′ of the storage capacitor Cst and the first capacitor electrode C21 of the holding capacitor Chd may include the same material as the fifth gate electrode G5″.

The second gate insulating layer 113 may be arranged on the fifth gate electrode G5″. A second capacitor electrode C12′ of the storage capacitor Cst and a second capacitor electrode C22 of the holding capacitor Chd may be arranged on the second gate insulating layer 113. The second capacitor electrode C12′ of the storage capacitor Cst and the second capacitor electrode C22 of the holding capacitor Chd may include a conductive material such as metal, for example, molybdenum (Mo), aluminum (Al), copper (Cu), titanium (Ti), etc., and may include a single-layer or multilayer structure including the above-described material.

A lower gate electrode of an oxide transistor may be arranged on the second gate insulating layer 113. For example, as shown in FIG. 11, the first lower gate electrode G1b″ of the first main transistor M1 and the second lower gate electrode G2b″ of the second main transistor M2 may be arranged on the second gate insulating layer 113. The second capacitor electrode C22 of the holding capacitor Chd may function as the first lower gate electrode G1b″. The second lower gate electrode G2b″ may include the same material as the first lower gate electrode G1b″.

The first interlayer insulating layer 114 may be arranged on the first lower gate electrode G1b″ and the second lower gate electrode G2b″. A first semiconductor layer A1″ of the first main transistor M1 and a second semiconductor layer A2″ of the second main transistor M2 may be arranged on the first interlayer insulating layer 114. The first semiconductor layer A1″ may include a channel region CH1″, and a source region S1″ and a drain region D1″ respectively arranged on both sides of the channel region CH1″. The second semiconductor layer A2″ may include a channel region CH2″, and a source region S2″ and a drain region D2″ respectively arranged on both sides of the channel region CH2″. The first semiconductor layer A1″ and the second semiconductor layer A2″ may include an oxide of at least one selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the first semiconductor layer A1″ and the second semiconductor layer A2″ may each be an InSnZnO (ITZO) semiconductor layer, an InGaZnO (IGZO) semiconductor layer, etc. At least a portion of an oxide semiconductor layer, for example, the source regions S1″ and S2″ and the drain regions D1″ and D2″, may be regions that have been made conductive through plasma treatment.

The first main transistor M1 may include a first upper gate electrode G1t″ arranged on the channel region CH1″ of the first semiconductor layer A1″ with the third gate insulating layer 115 therebetween, and the first lower gate electrode G1b″ facing the first upper gate electrode G1t″ with the channel region CH1″ therebetween. Likewise, the second main transistor M2 may include the second upper gate electrode G2t″ arranged on the channel region CH2″ of the second semiconductor layer A2″ with the third gate insulating layer 115 therebetween, and the second lower gate electrode G2b″ facing the second upper gate electrode G2t″ with the channel region CH2″ therebetween. The first upper gate electrode G1t″ and the second upper gate electrode G2t″ may include a conductive material including molybdenum (Mo), aluminum (Al), copper (Cu), titanium (Ti), etc., and may include a single-layer or multilayer structure including the above-described material.

As described above, the second upper gate electrode G2t″ and the second lower gate electrode G2b″ of the second main transistor M2, which is an oxide transistor, may be electrically connected to each other. The second upper gate electrode G2t″ and the second lower gate electrode G2b″ may be arranged on different layers and may face each other with the second semiconductor layer A2″ therebetween. The second upper gate electrode G2t″ and the second lower gate electrode G2b″ may be electrically connected to each other via a fourth connection electrode CE4 described below. The fourth connection electrode CE4 may be arranged above the second upper gate electrode G2t″ and may be connected to each of the second upper gate electrode G2t″ and the second lower gate electrode G2b″ via a contact hole.

When an oxide transistor, such as the second main transistor M2, has a double-gate structure in which an upper gate and a lower gate are connected to each other, compared to a single-gate structure, the thickness of a channel that may be formed in a channel region may increase and electron mobility may be increased. In addition, a voltage difference between the upper gate and the lower gate is eliminated, and thus, device stabilization may be achieved. Accordingly, by including the structure as described above, the display apparatus according to some embodiments may minimize a change in threshold voltage of an oxide transistor and relatively improve driving characteristics and reliability.

The second interlayer insulating layer 116 may be arranged on the first upper gate electrode G1t″ and the second upper gate electrode G2t″. The data line DL, a second connection pattern CP2, and the fourth connection electrode CE4 may be arranged on the second interlayer insulating layer 116. The data line DL, the second connection pattern CP2, and the fourth connection electrode CE4 may include a conductive material including molybdenum (Mo), aluminum (Al), copper (Cu), titanium (Ti), etc., and may include a single-layer or multilayer structure including the above-described material.

The fourth connection electrode CE4 may connect an upper gate electrode to a lower gate electrode of an oxide transistor in the display region DA. For example, as shown in FIG. 11, the fourth connection electrode CE4 may connect the second upper gate electrode G2t″ to the second lower gate electrode G2b″. One side of the fourth connection electrode CE4 may be connected to the second upper gate electrode G2t″ via a contact hole penetrating the second interlayer insulating layer 116. The other side of the fourth connection electrode CE4 may be connected to the second lower gate electrode G2b″ via a contact hole penetrating the second interlayer insulating layer 116, the third gate insulating layer 115, and the first interlayer insulating layer 114.

The first planarization layer 118 may be arranged on the data line DL, the second connection pattern CP2, and the fourth connection electrode CE4. The driving voltage line PL and a cover layer SL may be arranged on the first planarization layer 118. The driving voltage line PL and the cover layer SL may include a conductive material including molybdenum (Mo), aluminum (Al), copper (Cu), or titanium (Ti), and may include a single-layer or multilayer structure including the above-described material. According to some embodiments, the cover layer SL may cover a connection electrode for electrical connection between the first main transistor M1 and the third main transistor M3 (FIG. 10).

The second planarization layer 119 may be arranged on the driving voltage line PL and the cover layer SL, and the bank layer 120 and the light-emitting diode LED may be arranged on the second planarization layer 119. The light-emitting diode LED may include the pixel electrode 310, the intermediate layer 320, and the opposite electrode 330, and the bank layer 120 has an opening through which a portion of the pixel electrode 310 is exposed, thereby serving to define a pixel.

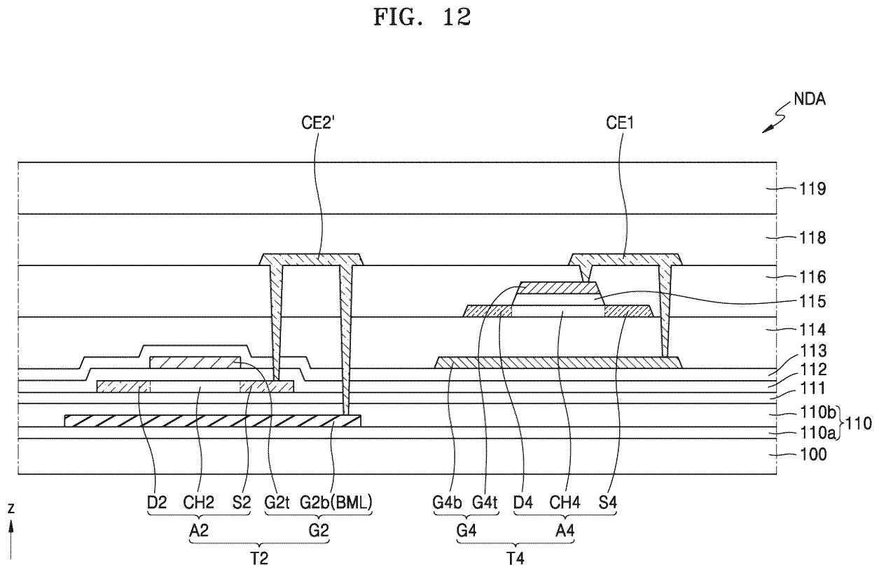

FIG. 12 is a cross-sectional view schematically showing a portion of a non-display region of the display apparatus 1 according to some embodiments. Referring to

FIG. 12, except for features of a second connection electrode CE2′, other features are the same as those described with reference to FIGS. 4A to 5. The same reference numerals for the components of FIG. 12 are substituted for those previously described with reference to FIGS. 4A to 5, and differences are mainly described in the following description.

Referring to FIG. 12, the lower metal layer BML may be arranged between the first barrier layer 110a and the second barrier layer 110b. At this time, the lower metal layer BML may function as a lower gate electrode of silicon transistors. For example, the lower metal layer BML may include the second lower gate electrode G2b of the second transistor T2.

The buffer layer 111 may be arranged on the lower metal layer BML and the barrier layer 110, and the second semiconductor layer A2 of the second transistor T2, which is a silicon transistor, may be arranged on the buffer layer 111. The second semiconductor layer A2 may include the second channel region CH2, and the second source region S2 and the second drain region D2 respectively arranged on both sides of the second channel region CH2.

The first gate insulating layer 112 may be arranged on the second semiconductor layer A2, and the second upper gate electrode G2t of the second transistor T2 may be arranged on the first gate insulating layer 112. The second gate insulating layer 113, the first interlayer insulating layer 114, and the second interlayer insulating layer 116 may be sequentially arranged on the second upper gate electrode G2t.

The first connection electrode CE1 and the second connection electrode CE2′ may be arranged on the second interlayer insulating layer 116. As described above, the first connection electrode CE1 may connect an upper gate to a lower gate of an oxide transistor. For example, the first connection electrode CE1 may connect the fourth upper gate electrode G4t to the fourth lower gate electrode G4b.

According to some embodiments, the second connection electrode CE2′ may connect a lower gate electrode of a silicon transistor to a source region of a silicon semiconductor layer. For example, as shown in FIG. 12, the second connection electrode CE2′ may connect the second lower gate electrode G2b of the second transistor T2 to the second source region S2 of the second semiconductor layer A2. In detail, one end of the second connection electrode CE2′ may be connected to the second source region S2 via a contact hole penetrating the second interlayer insulating layer 116, the first interlayer insulating layer 114, the second gate insulating layer 113, and the first gate insulating layer 112. The other end of the second connection electrode CE2′ may be connected to the second lower gate electrode G2b via a contact hole penetrating the second interlayer insulating layer 116, the first interlayer insulating layer 114, the second gate insulating layer 113, the first gate insulating layer 112, the buffer layer 111, and the second barrier layer 110b.

In other words, in a display apparatus according to some embodiments, a lower gate electrode of a silicon transistor may be connected to a source region of the silicon transistor rather than being connected to an upper gate electrode. When connected in the above manner, the second lower gate electrode G2b receives a voltage in conjunction with the potential of the second source region S2 of the second transistor T2, and thus, the second transistor T2 may be stabilized. In conclusion, in various embodiments, driving characteristics of a transistor may be adjusted as needed by connecting a lower gate electrode in various ways.

The display apparatus according to the embodiment may be applied to various electronic apparatuses. An electronic apparatus according to an embodiment of the present disclosure may include the display apparatus (e.g., the display apparatus of FIG. 1) described above, and may further include modules or apparatuses having additional functions in addition to the display apparatus.

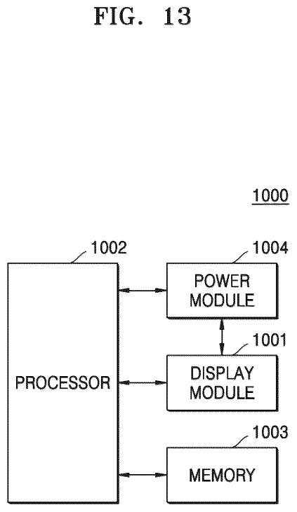

FIG. 13 is a block diagram of an electronic apparatus according to an embodiment.

Referring to FIG. 13, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

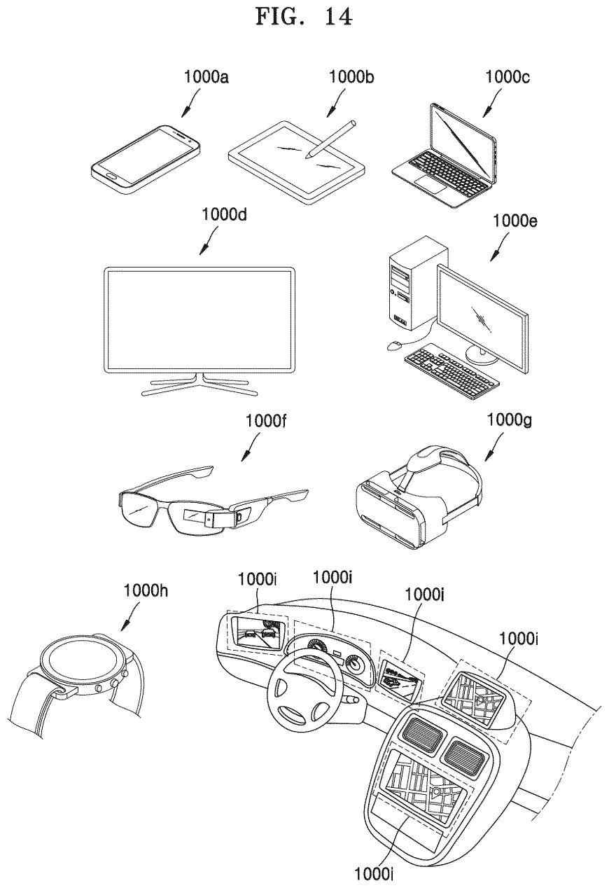

FIG. 14 is schematic diagrams of electronic apparatuses according to various embodiments.

Referring to FIG. 14, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

The display apparatus according to some embodiments as described above may include a driving circuit that may be configured to relatively stably output a gate signal by increasing reliability of a pixel device. The effects described above are only examples, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

1 what is claimed is:

1. A display apparatus comprising:
a substrate comprising a display region and a non-display region surrounding the display region; and
a gate driving circuit in the non-display region of the substrate and comprising a plurality of stages,
wherein each of the plurality of stages comprises a peripheral oxide transistor, comprising a first semiconductor layer comprising an oxide semiconductor, and a peripheral silicon transistor, comprising a second semiconductor layer comprising a silicon semiconductor,
the peripheral oxide transistor further comprises a first lower gate electrode under the first semiconductor layer and a first upper gate electrode above the first semiconductor layer, and
the first lower gate electrode and the first upper gate electrode are electrically connected to each other.

2. The display apparatus of claim 1, wherein each of the plurality of stages further comprises a first connection electrode that connects the first lower gate electrode to the first upper gate electrode.

3. The display apparatus of claim 2, wherein the first connection electrode is on the first upper gate electrode, and
the first connection electrode is connected to each of the first lower gate electrode and the first upper gate electrode via a contact hole.

4. The display apparatus of claim 2, wherein the peripheral silicon transistor further comprises a second lower gate electrode under the second semiconductor layer, and a second upper gate electrode above the second semiconductor layer.

5. The display apparatus of claim 4, wherein the second lower gate electrode is electrically connected to the second upper gate electrode.

6. The display apparatus of claim 5, wherein each of the plurality of stages further comprises a second connection electrode that connects the second lower gate electrode to the second upper gate electrode.

7. The display apparatus of claim 6, wherein the first connection electrode and the second connection electrode are on a same layer.

8. The display apparatus of claim 4, wherein the second semiconductor layer comprises a channel region, a source region on one side of the channel region, and a drain region on the other side of the channel region, and
the second lower gate electrode is electrically connected to the source region of the second semiconductor layer.

9. The display apparatus of claim 4, wherein the first semiconductor layer and the second semiconductor layer are on different layers.

10. The display apparatus of claim 9, wherein the second upper gate electrode is under the first lower gate electrode.

11. The display apparatus of claim 1, wherein the peripheral silicon transistor further comprises:
a first peripheral transistor connected between a first terminal, to which a start signal is input, and a first node, and comprising a gate connected to a clock terminal configured to receive a clock signal;
a second peripheral transistor connected between a second terminal configured to receive a first voltage, and a second node, and comprising a gate connected to the first node;
a third peripheral transistor connected between the first node and a third node and comprising a gate connected to a third terminal configured to receive a second voltage lower than the first voltage;
a fourth peripheral transistor connected between the second terminal and an output terminal and comprising a gate connected to the second node; and
a fifth peripheral transistor connected between the output terminal and the third terminal and comprising a gate connected to the third node, and
the peripheral oxide transistor further comprises a sixth peripheral transistor connected between the second node and the third terminal and comprising a gate connected to the third node.

12. The display apparatus of claim 11, wherein each of the plurality of stages further comprises:
a first capacitor connected between the output terminal and the third node; and
a second capacitor connected between the second terminal and the second node.

13. The display apparatus of claim 1, further comprising:
a pixel circuit in the display region of the substrate; and
a light-emitting diode electrically connected to the pixel circuit,
wherein the pixel circuit comprises a main oxide transistor, comprising a third semiconductor layer comprising an oxide semiconductor, and a main silicon transistor, comprising a fourth semiconductor layer comprising a silicon semiconductor,
the main oxide transistor further comprises a third lower gate electrode under the third semiconductor layer and a third upper gate electrode above the third semiconductor layer, and
the third semiconductor layer and the fourth semiconductor layer are on different layers.

14. The display apparatus of claim 13, wherein the pixel circuit further comprises a third connection electrode that electrically connects the third lower gate electrode to the third upper gate electrode.

15. The display apparatus of claim 13, wherein the main silicon transistor further comprises:
a first main transistor connected between a driving voltage line and the light-emitting diode and configured to control a current supplied to the light-emitting diode;
a second main transistor connected between a data line and a first main node connected to a first terminal of the first main transistor;
a third main transistor connected between the driving voltage line and the first main node; and
a fourth main transistor connected between the first main transistor and the light-emitting diode, and
the main oxide transistor further comprises:
a fifth main transistor connected between a second main node connected to a gate of the first main transistor and a third main node connected to a second terminal of the first main transistor; and
a sixth main transistor connected between a first initialization voltage line and the second main node.

16. The display apparatus of claim 15, wherein each of the fifth main transistor and the sixth main transistor comprises a structure in which the third lower gate electrode and the third upper gate electrode are electrically connected to each other.

17. The display apparatus of claim 15, wherein the pixel circuit further comprises a first main capacitor connected between the driving voltage line and the second main node, and
the main silicon transistor further comprises a seventh main transistor connected between a second initialization voltage line and the light-emitting diode.

18. The display apparatus of claim 13, wherein the main oxide transistor further comprises:
a first main transistor connected between a driving voltage line and the light-emitting diode and configured to control a current supplied to the light-emitting diode;
a second main transistor connected between a data line and a first main node connected to a gate of the first main transistor;
a third main transistor connected between a reference voltage line and the first main node; and
a fourth main transistor connected between an initialization voltage line and the light-emitting diode, and
the main silicon transistor further comprises:
a fifth main transistor connected between the driving voltage line and the first main transistor; and
a sixth main transistor connected between a second main node connected to a first terminal of the first main transistor and the light-emitting diode,
wherein at least one of the first main transistor, the second main transistor, the third main transistor, or the fourth main transistor has a structure in which the third lower gate electrode and the third upper gate electrode are electrically connected to each other.

19. The display apparatus of claim 18, wherein the pixel circuit further comprises:
a first main capacitor connected between the first main node and the second main node; and
a second main capacitor connected between the driving voltage line and the second main node.

20. An electronic apparatus comprising a display apparatus,
wherein the display apparatus comprises:
a substrate comprising a display region and a non-display region surrounding the display region; and
a gate driving circuit in the non-display region of the substrate and comprising a plurality of stages,
wherein each of the plurality of stages comprises a peripheral oxide transistor, comprising a first semiconductor layer comprising an oxide semiconductor, and a peripheral silicon transistor, comprising a second semiconductor layer comprising a silicon semiconductor,
the peripheral oxide transistor further comprises a first lower gate electrode under the first semiconductor layer and a first upper gate electrode above the first semiconductor layer, and
the first lower gate electrode and the first upper gate electrode are electrically connected to each other.
